(19) United States
(12) Patent Application Publication
(10) Pub. No.: US 2014/0315330 A1
(43) Pub. Date: Oct. 23, 2014

(54) MEASUREMENT DEVICE, MEASUREMENT METHOD, AND METHOD FOR MANUFACTURING SEMICONDUCTOR DEVICE

(71) Applicant: NIKON CORPORATION, Tokyo (JP)

(72) Inventor: Yoshihiko Fujimori, Yokohama-shi (JP)

(21) Appl. No.: 14/361,219

(22) PCT Filed: Nov. 29, 2012
(86) PCT No.: PCT/JP2012/080984

§ 371 Date: May 28, 2014

(30) Foreign Application Priority Data
Nov. 29, 2011 (JP) 2011-260929

(51) Int. Cl. G03F 7/20; H01L 21/66

(52) U.S. Cl. CPC G03F 7/70641; H01L 22/24
USPC 438/7; 356/121

(57) ABSTRACT

There is provided a measuring apparatus including: an illuminator configured to illuminate, with an illumination light, a substrate having a pattern formed by exposure on a surface; a detector configured to detect the illumination light modulated by the pattern to output a detection signal; and a measuring unit configured to measure an exposure condition of the pattern of a desired portion by using the detection signals detected at a plurality of portions of the pattern.

### TECHNICAL FIELD

The present invention relates to a measuring apparatus and a measuring method for measuring an exposure condition of a pattern subjected to exposure in relation to each of predetermined areas on a substrate. The present invention also relates to a method for producing a semiconductor device based on the use of such a measuring method.

### BACKGROUND ART

In the exposure apparatus represented by those based on the step-and-scan system, it is extremely important to manage the focus (focusing state of a pattern on a wafer surface). Accordingly, for example, test exposure is performed prior to the production to perform the adjustment so that the image plane of a pattern (semiconductor circuit pattern) to be projected onto a wafer by an exposure apparatus is coincident with the exposure surface of the wafer (surface processed with a resist and a top coat). In order to measure the state of the focus of the exposure apparatus, for example, such a method is known that a mask (reticle) for exclusive use is used to perform the exposure with a test pattern and perform the development, and the focus offset amount is measured from the obtained positional deviation of the test pattern (see, for example, Patent Document 1).

### CITATION LIST

### Patent Literature

### Patent Literature 1: United States Patent Publication No. 2002/0100012,

### SUMMARY OF INVENTION

### Technical Problem

In the meantime, the line width and/or the shape differ(s) in some cases between the actual pattern and the pattern for exclusive use for obtaining or determining the focus offset. A problem arises such that the focus offset (focus state or state of focus), which is obtained or determined with the pattern for exclusive use, is different from the focus offset state of the actual pattern (semiconductor circuit pattern). Many portions having different functions sometimes exist in one chip depending on the device. A problem arises such that the divergence or estrangement tends to occur between the focus offset determined from the pattern for exclusive use and the focus offset of the actual pattern.

The present teaching has been made taking the foregoing problems into consideration, an object of which is to provide an apparatus and a method which make it possible to measure the focus state of a device pattern to be projected onto a wafer.

### Solution to the Problem

In order to achieve the object as described above, according to the present teaching, there is provided a measuring apparatus including an illuminator configured to illuminate, with an illumination light, a substrate having a pattern formed by exposure on a surface; a detector configured to detect the illumination light modulated by the pattern to output a detection signal; and a measuring unit configured to measure an exposure condition of the pattern of a desired portion by using the detection signals detected at a plurality of portions of the pattern.

In the measuring apparatus constructed as described above, the measuring unit can be configured to measure the exposure condition of the pattern of the desired portion by using the detection signals detected at a plurality of portions including the desired portion.

In the measuring apparatus constructed as described above, the measuring unit can be configured to measure the exposure condition of the pattern of the desired portion from the detection signal detected at a portion disposed around the desired portion.

In the measuring apparatus constructed as described above, the measuring unit can be configured to measure the exposure condition of the pattern of the desired portion from the detection signal detected at the desired portion and a signal corresponding to the desired portion determined from the detection signal detected at a portion other than the desired portion.

In the measuring apparatus constructed as described above, the measuring unit can be configured to determine the detection signal corresponding to the desired portion by means of interpolation from the signal detected at the portion disposed around the desired portion.

In the measuring apparatus constructed as described above, the measuring unit can be configured to measure the exposure condition of the pattern of the desired portion by using the detection signals detected at the desired portion and the portion disposed around the desired portion, the portion disposed around the desired portion being correlated with the desired portion.

In the measuring apparatus constructed as described above, the construction can be made such that a detection condition for detecting the modulated illumination light is set for each of the portions.

In the measuring apparatus constructed as described above, the detector can be configured to detect modulation based on diffraction or polarization caused by the pattern.

The measuring apparatus can further comprise a storage unit which is configured to previously store the detection signals detected with patterns formed under a plurality of exposure conditions; wherein the measuring unit can be configured to measure the exposure condition of the pattern of the desired portion on the surface by comparing the detection signal stored in the storage unit with the detection signal detected by the detector.

In the measuring apparatus constructed as described above, the exposure condition measured by the measuring unit can be at least one of a focus state and an exposure amount in the exposure.

In another aspect, according to the present teaching, there is provided a measuring method including illuminating, with an illumination light, a substrate having a pattern formed by exposure on a surface; detecting the illumination light modulated by the pattern to output a detection signal; and measuring an exposure condition of the pattern of a desired portion by using the detection signals detected at a plurality of portions of the pattern.

In the measuring method described above, the exposure condition of the pattern of the desired portion can be measured by using the detection signals detected at a plurality of portions including the desired portion.

In the measuring method described above, the exposure condition of the pattern of the desired portion can be measured from the detection signal detected at the desired portion and a signal corresponding to the desired portion determined from the detection signal detected at a portion other than the desired portion.

In the measuring method described above, a signal corresponding to the desired portion can be determined from the detection signal detected in a partial area disposed around the desired portion to measure the exposure condition of the pattern of the desired portion.

In the measuring method described above, the detection signal corresponding to the desired portion can be determined by means of interpolation from the signal detected at the portion disposed around the desired portion.

In the measuring method described above, the exposure condition of the pattern of the desired portion can be measured from the detection signal detected at the desired portion and a signal corresponding to the desired portion determined from the detection signal detected at a portion correlated with the desired portion, the portion being other than the desired portion.

In the measuring method described above, a detection condition for detecting the modulated illumination light can be set for each of the portions.

In the measuring method described above, modulation based on diffraction or polarization caused by the pattern can be detected in the detection.

The measuring method described above can further include previously storing the detection signals detected with patterns formed under a plurality of exposure conditions; and measuring the exposure condition of the pattern of the desired portion on the surface by comparing the stored detection signal with the detected detection signal.

In the measuring method described above, the exposure condition to be measured can be at least one of a focus state and an exposure amount in the exposure.

In still another aspect, according to the present teaching, there is provided a method for producing a semiconductor device, including a lithography step of exposing a surface of a substrate with a pattern; the method for producing the semiconductor device including measuring an exposure condition during the exposure for the substrate provided with the pattern by using the measuring method according to the present teaching after the exposure; correcting an exposure condition based on the measured exposure condition; and exposing the surface of the substrate with the pattern under a corrected exposure condition.

### Effects of Invention

According to the present teaching, it is possible to measure the focus state provided when the pattern is subjected to the exposure, from the pattern of the device formed on the wafer.

### BRIEF DESCRIPTION OF DRAWINGS

FIG. 1 shows a schematic arrangement of a surface inspection apparatus.

FIG. 2 shows a state in which a polarizing filter is inserted into an optical path of the surface inspection apparatus.

FIG. 3 shows an appearance of a surface of a semiconductor wafer.

FIG. 4 shows plan views illustrating the arrangement structure of repeating patterns in one shot.

FIG. 5 shows a perspective view illustrating a protrusion/recess structure of the repeating pattern.

FIG. 6 illustrates an inclination state concerning the incidence plane of the linearly polarized light and the repeating direction of the repeating pattern.

FIG. 7 shows a flow chart illustrating a method for determining the inclination of an image plane of an exposure apparatus.

FIG. 8 shows a table illustrating focus offset amounts set on a condition-varied wafer.

FIG. 9 shows an example of the condition-varied wafer.

FIG. 10 shows an example of the focus curve.

FIG. 11 shows a graph illustrating the relationship between the focus curve and the best focus.

FIG. 12 shows a distribution of the focus offset amount in the shot.

FIG. 13 shows a flow chart illustrating a method for determining the focus state during the exposure by the exposure apparatus (first embodiment).

FIG. 14 shows focus curves and diffraction images of the condition-varied wafer acquired by image pickup under different conditions.

FIG. 15 shows a situation in which the focus offset amount is determined from diffraction images of the wafer acquired by image pickup under different conditions.

FIG. 16 shows a graph illustrating the relationship between the focus curve and the signal intensity measured value.

FIG. 17 shows a variation state of the focus with respect to the surface of the wafer.

FIG. 18 shows a flow chart illustrating a method for determining the focus state during the exposure by the exposure apparatus (second embodiment).

FIG. 19 shows an example of the calculation formula of linear interpolation.

FIG. 20 shows plan views illustrating the arrangement structure of repeating patterns in one shot (second embodiment).

FIG. 21 shows a flow chart illustrating a method for determining the focus state during the exposure by the exposure apparatus (third embodiment).

FIG. 22 shows plan views illustrating the arrangement structure of repeating patterns in one shot (fourth embodiment).

FIG. 23 shows a flow chart illustrating a method for determining the focus state during the exposure by the exposure apparatus (fourth embodiment).

FIG. 24 shows a flow chart illustrating a specified embodiment of a method for dividing the shot of Step S506 in the flow chart shown in FIG. 23.

FIG. 25 shows a flow chart illustrating a modified embodiment of the method for dividing the shot shown in FIG. 24.

FIG. 26 shows a flow chart illustrating a method for determining the focus state during the exposure by the exposure apparatus (fifth embodiment).

FIG. 27 shows a schematic arrangement of an exposure system.

FIG. 28 shows a flow chart illustrating a method for producing a semiconductor device.

FIG. 29 shows a flow chart illustrating a lithography step.

FIG. 30 shows a schematic arrangement of a microscope apparatus.

FIG. 31 shows an arrangement in which a polarizer and an analyzer are removed from the optical path of the microscope apparatus and a wafer tilt mechanism is provided.

FIG. 32 shows the relationship between the illumination system falling angle T and the tilt angle θ.

### DESCRIPTION OF EMBODIMENTS

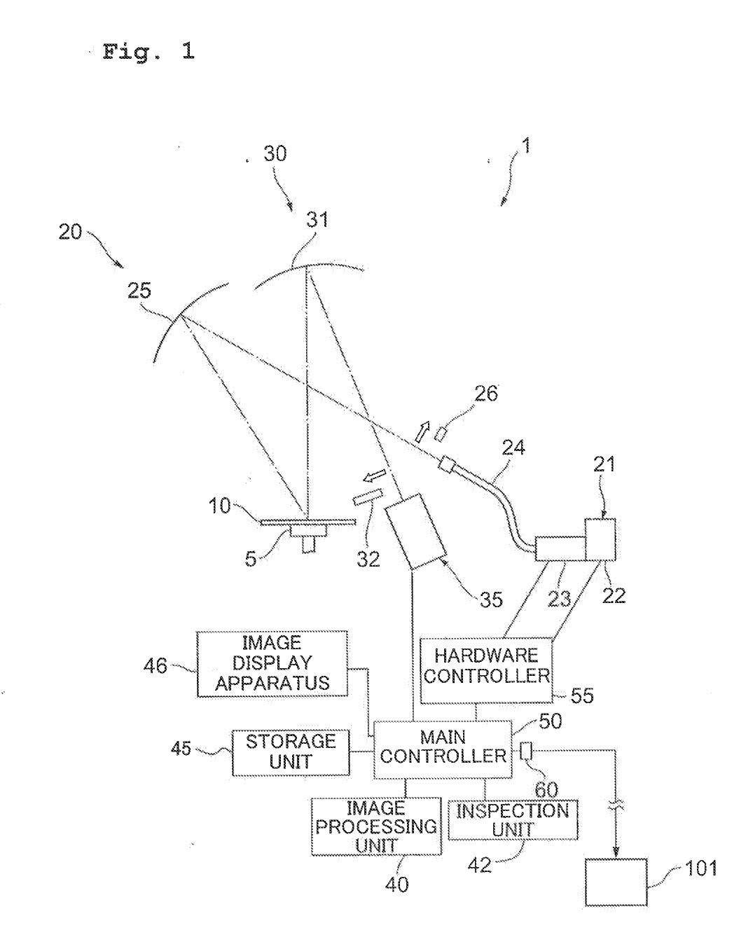

An embodiment of the present teaching will be explained below with reference to the drawings. FIG. 1 shows a surface inspection apparatus 1 provided with the function of the measuring apparatus according to the present teaching. At first, an explanation will be made about the schematic arrangement of the surface inspection apparatus with reference to FIG. 1.

The surface inspection apparatus 1 is constructed to include a stage 5 which supports, by means of the vacuum suction, a substantially disk-shaped semiconductor wafer 10 (hereinafter referred to as “wafer”) transported by an unillustrated transport apparatus. The stage 5 supports the wafer 10 rotatably (rotatably in the surface of the wafer 10) by using the axis of rotation of the axis of rotation symmetry of the wafer 10 (central axis of the stage 5). The direction of the wafer, which is brought about by the rotation, is conveniently referred to as “wafer orientation angle” (angle based on the notch or the orientation flat). Further, the stage 5 can tilt (incline) the wafer 10 about the center of the axis passing through the support surface for supporting the wafer 10 or the plane parallel to the support surface. It is possible to adjust the angle of incidence of the illumination light.

The surface inspection apparatus 1 is constructed to further include an illumination system 20 which irradiates the illumination light as the parallel light onto the entire surface of the wafer 10 supported by the stage 5, a light-receiving system 30 which collects, for example, the regularly reflected light, the diffracted light, and the scattered light allowed to come from the entire surface of the wafer 10 when the irradiation of the illumination light is received, an image pickup device 35 which detects the image of the surface of the wafer 10 by receiving the light collected by the light-receiving system 30, an image processing unit 40, an inspection unit 42, a storage unit 45, an image display apparatus 46, a main controller 50, and a hardware controller 55 which is connected to the main controller 50.

The illumination system 20 is constructed to include an illuminator 21 which emits or radiates the illumination light, and an illumination-side concave mirror 25 which reflects the illumination light allowed to outgo from the illuminator 21 toward the surface of the wafer 10. The illuminator 21 is constructed to include a light source section 22 which is, for example, a metal halide lamp or a mercury lamp, a light controller 23 which extracts (selectively transmits) the light having a predetermined wavelength of the light allowed to come from the light source section 22 so that the intensity is regulated or modulated, and an optical guide fiber 24 which guides the light allowed to come from the light controller 23 as the illumination light to the illumination-side concave mirror 25. The main controller 50 controls the light source section 22 and the light controller 23 by the aid of the hardware controller 55.

The light, which is allowed to outgo from the light source section 22, passes through the light controller 23, and the light is controlled into the illumination light of a predetermined intensity having a predetermined wavelength (for example, a wavelength of 248 nm). The illumination light is allowed to outgo from the optical guide fiber 24 to the illumination-side concave mirror 25. The radiating portion (light outgoing portion) of the optical guide fiber 24 is arranged on the focal plane of the illumination-side concave mirror 25. Therefore, the light is converted into a parallel light flux by the illumination-side concave mirror 25, and the light is radiated onto the surface of the wafer 10 supported by the stage 5. The illumination-side concave mirror 25 and a receiving-side concave mirror 31 described later on are fixed. However, the relationship between the incidence angle (angle of incidence) and the outgoing angle (light-exit angle) of the illumination light with respect to the wafer 10 can be adjusted by changing the placement angle (support angle) of the wafer 10 by tilting (inclining) the stage 5.

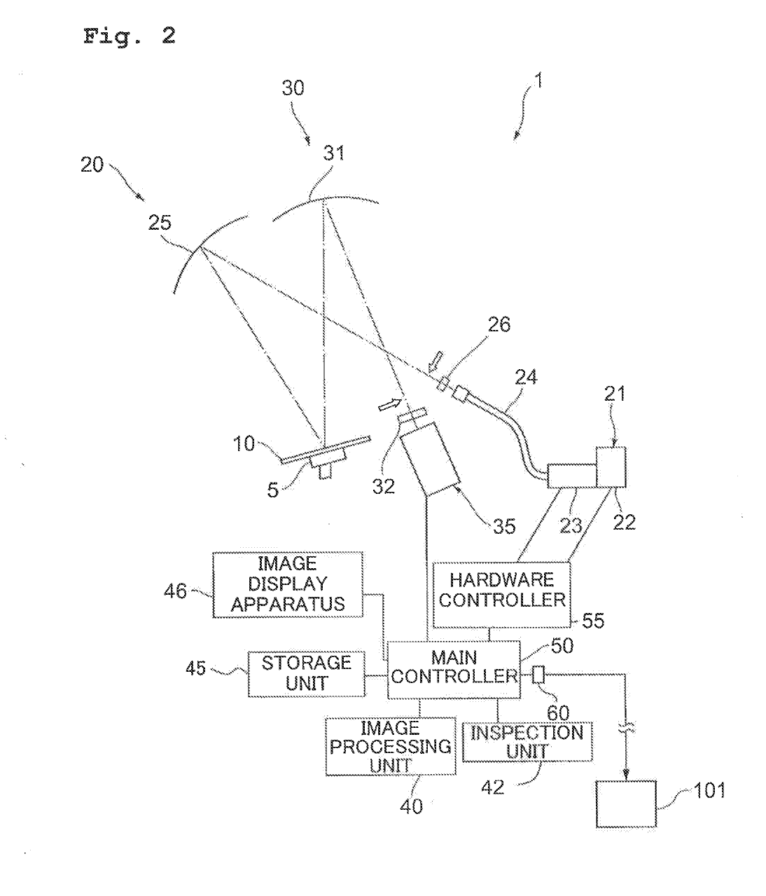

An illumination-side polarizing filter 26 is provided between the optical guide fiber 24 and the illumination-side concave mirror 25 so that the illumination-side polarizing filter 26 can be inserted into and ejected from the optical path. The inspection (hereinafter conveniently referred to as “diffraction inspection”), which utilizes the diffracted light, is performed in a state in which the illumination-side polarizing filter 26 is ejected from the optical path as shown in FIG. 1. On the other hand, the inspection (hereinafter conveniently referred to as “PER inspection”), which utilizes the polarized light (change of the polarization state caused by the structural double refraction), is performed in a state in which the illumination-side polarizing filter 26 is inserted into the optical path as shown in FIG. 2 (details of the illumination-side polarizing filter 26 will be described later on).

The outgoing light (diffracted light, regularly reflected light, or scattered light), which is allowed to outgo from the surface of the wafer 10 irradiated with the illumination light by the illumination system 20, is collected by the light-receiving system 30. The light-receiving system 30 is constructed to include the receiving-side concave mirror 31 which is arranged opposingly to the stage 5. The outgoing light (diffracted light, regularly reflected light, or scattered light), which is collected by the receiving-side concave mirror 31, arrives at the image pickup surface of the image pickup device 35, and the image of the wafer 10 is formed (subjected to the imaging).

A receiving-side polarizing filter 32 is provided between the receiving-side concave mirror 31 and the image pickup device 35 so that the receiving-side polarizing filter 32 can be inserted into and ejected from the optical path. The diffraction inspection is performed in a state in which the receiving-side polarizing filter 32 is ejected from the optical path as shown in FIG. 1. On the other hand, the PER inspection is performed in a state in which the receiving-side polarizing filter 32 is inserted into the optical path as shown in FIG. 2 (details of the receiving-side polarizing filter 32 will be described later on).

In the image pickup device 35, the image of the surface of the wafer 10, which is formed on the image pickup surface, is subjected to the photoelectric conversion to generate an image signal (digital image data) which is sent to the main controller 50. The main controller 50 receives the image signal of the image of the surface of the wafer 10 from the image pickup device 35, and the image signal is outputted to the image processing unit 40. The image processing unit 40 generates the digital image of the wafer 10 based on the image signal of the wafer 10 inputted from the image pickup device 35. The digital image of the wafer 10, which is generated by the image processing unit 40, is sent to the inspection unit 42 via the main controller 50. The inspection unit 42 compares the image data of the wafer 10 sent from the main controller 50 (image processing unit 40) with the image data of a non-defective wafer previously stored in the storage unit 45 to inspect the presence or absence of any defect (abnormality) on the surface of the wafer 10. Further, the inspection result obtained by the inspection unit 42 and the image of the wafer 10 obtained thereby are subjected to the output display by the image display apparatus 46, and the inspection result and the image are sent to and stored in the storage unit 45.

The inspection unit 42 can determine (obtain) the focus state during the exposure performed by the exposure apparatus 101 by utilizing the image of the wafer (details will be described later on). When the inspection of the presence or absence of the defect on the surface of the wafer 10 is easily affected by the under layer of the wafer 10, the influence of the under layer can be reduced by arranging the illumination-side polarizing filter 26 for the illumination system 20 so that the illumination light is the s-polarized light and the illumination is performed by using the s-polarized light. Also in this case, the receiving-side polarizing filter 32 is ejected from the optical path.

In the meantime, as for the wafer 10, the resist film, which is disposed at the uppermost layer, is exposed with a predetermined mask pattern by effecting the projection by means of the exposure apparatus 101. After performing the development by a developing apparatus (not shown), the wafer 10 is transported by an unillustrated transport apparatus from an unillustrated wafer cassette or the developing apparatus onto the stage 5. In this procedure, the wafer 10 is transported onto the stage 5 in a state in which the alignment is performed based on the pattern of the wafer 10 or the outer edge portion (for example, the notch or the orientation flat).

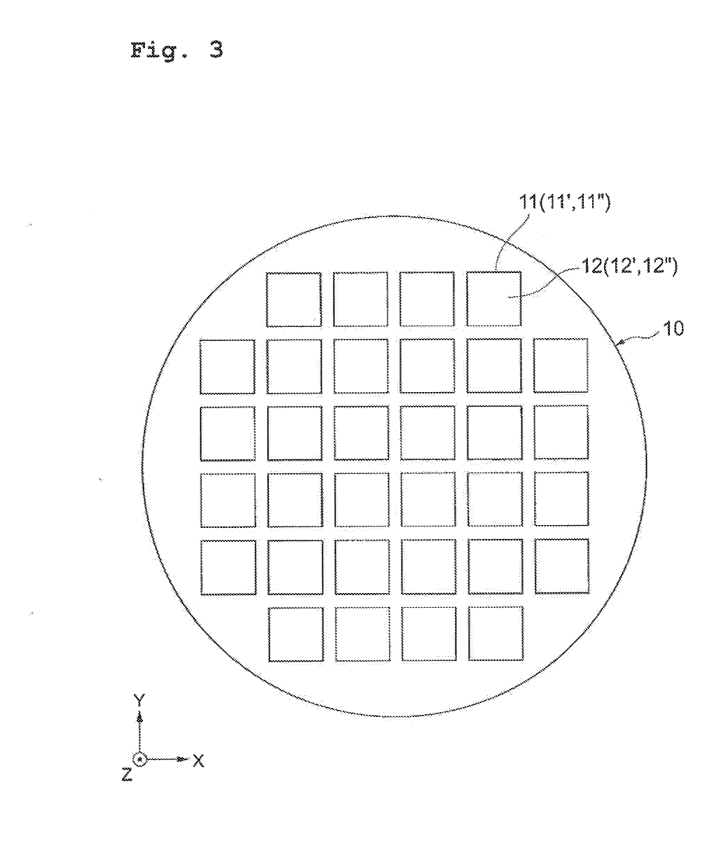

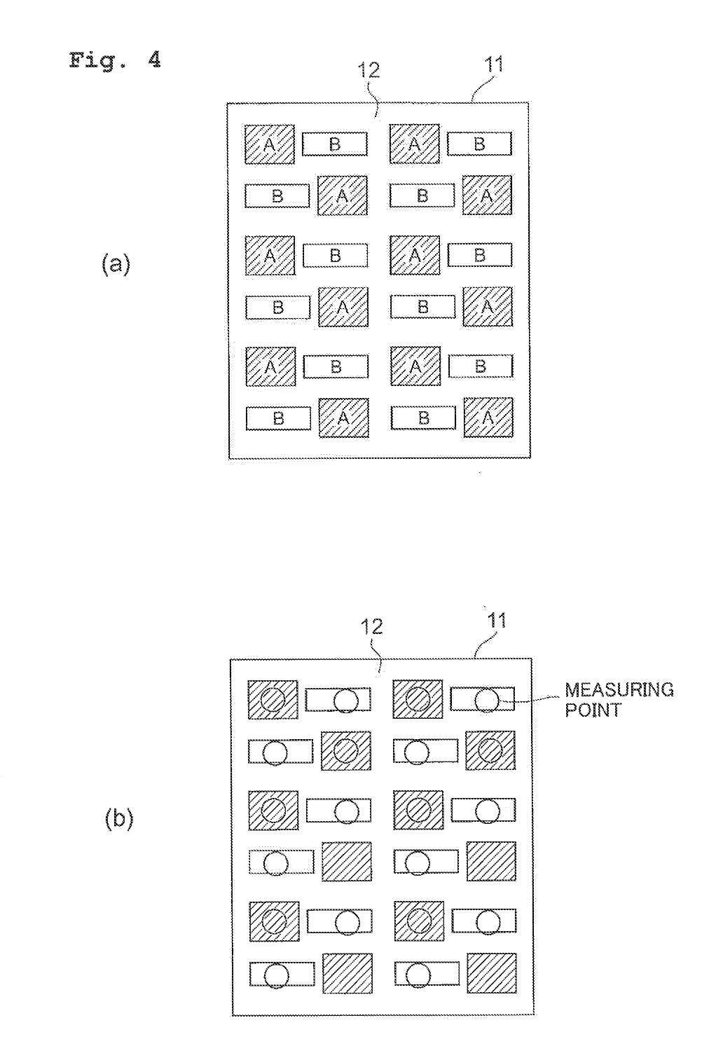

As shown in FIG. 3, a plurality of chip areas 11 are arranged laterally and longitudinally (in the XY directions as shown in FIG. 3) on the surface of the wafer 10. A repeating pattern 12 such as a line pattern, a hole pattern or the like is formed as the semiconductor pattern in each of the chip areas 11. For example, as shown in FIG. 4A, the repeating pattern 12 is constructed to include a first pattern area A which is composed of one type or a plurality of types of repeating pattern or patterns and a second pattern area B which has a repeating pattern or patterns constructed differently from the first pattern area A. The device, which is formed on the wafer 10, is a logic device in which the areal size of the pattern formed on the surface is small and a plurality of areas having differently constructed patterns exist.

A plurality of chip areas are included in one shot of the exposure in many cases. However, in FIG. 3, one chip occupied one shot in order to understand the drawing more comprehensively. In the surface inspection apparatus 1, the processing speed is improved by performing the illumination and the light receiving collectively or integrally for the entire surface. However, the illumination and the light receiving can be also performed by using an object of a range which is equal to or smaller than 1 shot.

The exposure apparatus 101 is the exposure apparatus based on the step-and-scan system as described above. The exposure apparatus 101 is electrically connected to a signal output unit 60 of the surface inspection apparatus 1 of this embodiment via a cable or the like. The exposure apparatus 10 is constructed so that the adjustment can be performed for the exposure control based on the data (signal) supplied from the surface inspection apparatus 1.

In order to perform the diffraction inspection for the surface of the wafer 10 by using the surface inspection apparatus 1 constructed as described above, the illumination-side polarizing filter 26 and the receiving-side polarizing filter 32 are firstly ejected from the optical path as shown in FIG. 1, and the wafer 10 is transported onto the stage 5 by means of the unillustrated transport apparatus. The position information of the pattern formed on the surface of the wafer 10 is acquired by an unillustrated alignment mechanism during the transport. The wafer 10 can be placed in a predetermined direction at a predetermined position on the stage 5.

Subsequently, the stage 5 is rotated so that the illumination direction on the surface of the wafer 10 is coincident with the repeating direction of the pattern (perpendicular to the line in the case of a line pattern). It is assumed that P represents the pitch of the pattern, λ represents the wavelength of the illumination light radiated onto the surface of the wafer 10, θ1 represents the angle of incidence of the illumination light, and θ2 represents the outgoing angle of nth-order diffracted light. On this assumption, according to the Huygens principle, the setting is made to fulfill the following numerical expression (stage 5 is tilted).

P=n×λ/{sin(θ1)−sin(θ2)} (1)

Subsequently, the illumination light is radiated onto the surface of the wafer 10 by means of the illumination system 20. When the illumination light is radiated onto the surface of the wafer 10 under the condition as described above, the light, which is allowed to outgo from the light source section 22 of the illuminator 21, passes through the light controller 23, and the light is adjusted into the illumination light of a predetermined intensity having a predetermined wavelength (for example, a wavelength of 248 nm). The illumination light is allowed to outgo from the optical guide fiber 24 to the illumination-side concave mirror 25. The illumination light, which is reflected by the illumination-side concave mirror 25, behaves as the parallel light flux which is radiated onto the surface of the wafer 10. The diffracted light, which is diffracted by the surface of the wafer 10, is collected by the receiving-side concave mirror 31, and the light arrives at the image pickup surface of the image pickup device 35. Thus, the image (diffraction image) of the wafer 10 is formed (subjected to the imaging). The condition of the diffracted light, which is decided by the combination of, for example, the wafer orientation angle, the illumination wavelength, the illumination angle (angle of incidence), the outgoing angle, and the order of diffraction, is referred to as “diffraction condition”.

Accordingly, the image pickup device 35 photoelectrically converts the image of the surface of the wafer 10 formed on the image pickup surface to form an image signal. The image signal is outputted to the image processing unit 40 via the main controller 50. The image processing unit 40 generates a digital image of the wafer 10 (digital image of the wafer 10 based on the diffracted light is conveniently referred to as “diffraction image”) based on the image signal of the wafer 10 inputted from the image pickup device 35. Further, when the diffraction image of the wafer 10 is generated, the image processing unit 40 sends the diffraction image to the inspection unit 42 via the main controller 50. The inspection unit 42 compares the diffraction image data of the wafer 10 with the image data of the non-defective wafer previously stored in the storage unit 45 to inspect the presence or absence of any defect (abnormality) on the surface of the wafer 10. The inspection result and the diffraction image of the wafer 10 obtained thereby, which are acquired by the image processing unit 40 and the inspection unit 42, are subjected to the output display by the image display apparatus 46, and the result and the image are stored in the storage unit 45. The signal intensity (brightness value) of the diffraction image of the non-defective wafer exhibits the highest signal intensity (brightness value) in many cases. Therefore, for example, when the change of the signal intensity (brightness change), which is obtained by making comparison with the non-defective wafer, is larger than a preset threshold value (allowable value), it is judged that the situation is “abnormal”. When the change of the signal intensity (brightness change) is smaller than the threshold value, it is judged that the situation is “normal”.

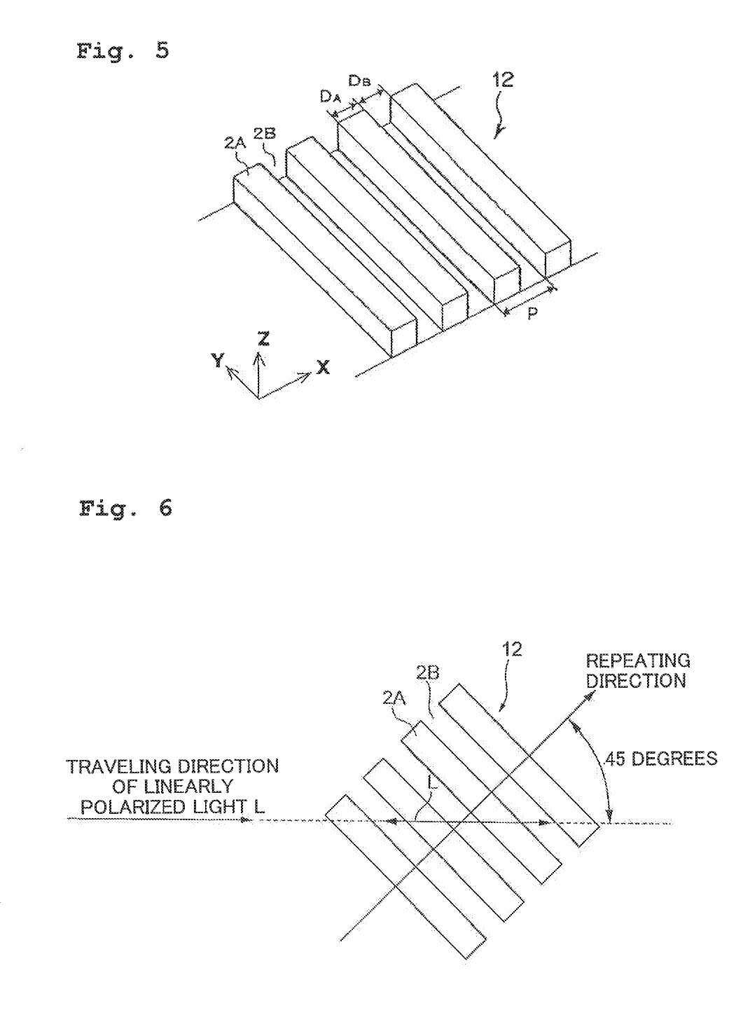

Next, an explanation will be made about a case in which the PER inspection is performed for the surface of the wafer 10 by means of the surface inspection apparatus 1. In this section, it is assumed that the repeating pattern 12 is a resist pattern (line pattern) in which a plurality of line portions 2A are arranged at constant pitches (intervals) P in the transverse direction (X direction) thereof as shown in FIG. 5. The spaces between the mutually adjoining line portions 2A are space portions 2B. The arrangement direction (X direction) of the line portions 2A is referred to as “repeating direction of the repeating pattern 12”.

In this case, it is assumed that the designed value of the line width D_{A} of the line portion 2A of the repeating pattern 12 is ½ of the pitch P. When the repeating pattern 12 is formed as exactly as assumed by the designed value, then the line width D_{A} of the line portion 2A is equal to the line width D_{B} of the space portion 2B, and the volume ratio between the line portion 2A and the space portion 2B is approximately 1:1. On the contrary, when the exposure focus, which is provided when the repeating pattern 12 is formed, is deviated from the proper value, then the pitch P is not changed, but the line width D_{A} of the line portion 2A is different from the designed value, and the line width D_{A} of the line portion 2A is also different from the line width D_{B} of the space portion 2B. Therefore, the volume ratio between the line portion 2A and the space portion 2B is deviated from the value of approximately 1:1.

In the PER inspection, the inspection is performed in relation to the abnormality of the repeating pattern 12 by utilizing the change of the volume ratio between the line portion 2A and the space portion 2B in the repeating pattern 12 as described above. In order to simplify the explanation, it is assumed that the ideal volume ratio (designed value) is 1:1. The change of the volume ratio arises resulting from the deviation of the exposure focus from the proper value. The volume ratio can be also expressed as “area ratio of the cross-sectional shape” in different words.

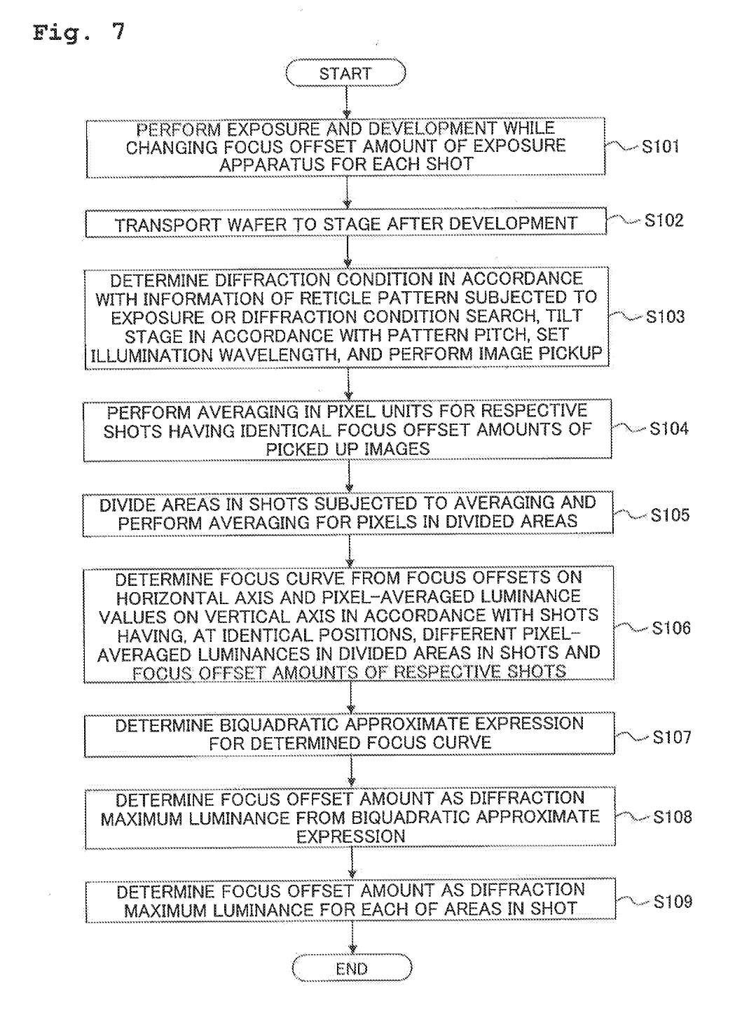

In the PER inspection, as shown in FIG. 2, the illumination-side polarizing filter 26 and the receiving-side polarizing filter 32 are inserted into the optical path. When the PER inspection is performed, the stage 5 tilts the wafer 10 to such an inclination angle that the regularly reflected light, which comes from the wafer 10 irradiated with the illumination light, can be received by the light-receiving system 30. Further, the stage 5 stops at a predetermined position of rotation to perform the support so that the repeating direction of the repeating pattern 12 on the wafer 10 is inclined obliquely by 45 degrees with respect to the vibration direction of the illumination light (linearly polarized light L) on the surface of the wafer 10 as shown in FIG. 6, for the following reason. That is, it is intended to maximally raise the light amount of the inspection of the repeating pattern 12. When the angle is 22.5 degrees or 67.5 degrees, the sensitivity of the inspection is raised. The angle is not limited thereto, and the setting can be made in any arbitrary angle direction.

The illumination-side polarizing filter 26 is arranged between the optical guide fiber 24 and the illumination-side concave mirror 25, and the transmission axis thereof (vibration direction of the electric field of the polarization capable of passing through the filter) is set to a predetermined orientation. The linearly polarized light is extracted from the light allowed to come from the illuminator 21 in accordance with the transmission axis. In this procedure, the light outgoing portion (light-exit portion) of the optical guide fiber 24 is arranged at the focus position of the illumination-side concave mirror 25. Therefore, the illumination-side concave mirror 25 converts the light transmitted through the illumination-side polarizing filter 26 into the parallel light flux with which the wafer 10 as the substrate is illuminated. In this way, the light, which is radiated from the optical guide fiber 24, passes along the illumination-side polarizing filter 26 and the illumination-side concave mirror 25, and the light is converted into the linearly polarized light L of p polarization (see FIG. 6). The light is radiated as the illumination light onto the entire surface of the wafer 10.

In this procedure, the traveling direction of the linearly polarized light L (direction of the main light beam of the linearly polarized light L allowed to arrive at an arbitrary point on the surface of the wafer 10) is substantially parallel to the optical axis. Therefore, the angles of incidence of the linearly polarized light L at the respective points of the wafer 10 are identical with each other because of the parallel light flux. Further, the linearly polarized light L, which comes into the wafer 10, is the p polarized light. Therefore, as shown in FIG. 6, when the repeating direction of the repeating pattern 12 is set at the angle of 45 degrees with respect to the incidence plane of the linearly polarized light L (traveling direction of the linearly polarized light L on the surface of the wafer 10), the angle, which is formed by the vibration direction of the linearly polarized light L on the surface of the wafer 10 and the repeating direction of the repeating pattern 12, is also set to 45 degrees. In other words, the linearly polarized light L comes into the repeating pattern 12 so that the linearly polarized light L obliquely traverses the repeating pattern 12 in a state in which the vibration direction of the linearly polarized light L on the surface of the wafer 10 is inclined by 45 degrees with respect to the repeating direction of the repeating pattern 12.

The regularly reflected light, which is reflected by the surface of the wafer 10, is collected by the receiving-side concave mirror 31 of the light-receiving system 30, and the light arrives at the image pickup surface of the image pickup device 35. However, when the light is reflected by the repeating pattern 12, the polarization state of the linearly polarized light L is changed on account of the structural double refraction in the repeating pattern 12. The receiving-side polarizing filter 32 is arranged between the receiving-side concave mirror 31 and the image pickup device 35. The orientation of the transmission axis of the receiving-side polarizing filter 32 is set to be perpendicular to the transmission axis of the illumination-side polarizing filter 26 described above (crossed Nicol state). Therefore, the polarized light component (for example, the component of s polarization), which is included in the regularly reflected light allowed to come from the wafer 10 (repeating pattern 12) and which has the vibration direction substantially perpendicular to the linearly polarized light L, is allowed to pass through the receiving-side polarizing filter 32, and the light can be guided to the image pickup device 35. As a result, the reflection image of the wafer 10 is formed on the image pickup surface of the image pickup device 35 by the polarized light component which is included in the regularly reflected light allowed to come from the wafer 10 and which has the vibration direction substantially perpendicular to the linearly polarized light L. The sensitivity can be improved by allowing the receiving-side polarizing filter 32 to be rotatable about the center of the optical axis and performing the adjustment so that the minor axis direction of the elliptically polarized regularly reflected light is matched with the transmission axis of the receiving-side polarizing filter 32. Also in this case, the angle can be adjusted by several degrees, which is included in the category of substantial perpendicularity.

In order to perform the PER inspection for the surface of the wafer 10 by means of the surface inspection apparatus 1, the illumination-side polarizing filter 26 and the receiving-side polarizing filter 32 are firstly inserted into the optical path as shown in FIG. 2, and the wafer 10 is transported onto the stage 5 by means of the unillustrated transport apparatus. The position information of the pattern formed on the surface of the wafer 10 is acquired by the unillustrated alignment mechanism during the transport. The wafer 10 can be placed in a predetermined direction at a predetermined position on the stage 5. In this procedure, the stage 5 tilts the wafer 10 to an angle of inclination at which the regularly reflected light, which comes from the wafer 10 irradiated with the illumination light, can be received by the light-receiving system 30. Further, the stage 5 stops at a predetermined position of rotation to perform the support so that the repeating direction of the repeating pattern 12 on the wafer 10 is inclined obliquely by 45 degrees with respect to the vibration direction of the illumination light (linearly polarized light L) on the surface of the wafer 10.

Subsequently, the illumination light is radiated onto the surface of the wafer 10 by the illumination system 20. When the illumination light is radiated onto the surface of the wafer 10 under the condition as described above, then the light, which is emitted (allowed to outgo) from the optical guide fiber 24 of the illuminator 21, passes along the illumination-side polarizing filter 26 and the illumination-side concave mirror 25, and the light is converted into the linearly polarized light L of p polarization which is radiated as the illumination light onto the entire surface of the wafer 10. The regularly reflected light, which is reflected by the surface of the wafer 10, is collected by the receiving-side concave mirror 31, and the light arrives at the image pickup surface of the image pickup device 35 to form the image (reflected image) of the wafer 10.

In this procedure, the polarization state of the linearly polarized light L is changed on account of the structural double refraction on the repeating pattern 12. The polarized light component, which is included in the regularly reflected light allowed to come from the wafer 10 (repeating pattern 12) and which has the vibration direction substantially perpendicular to the linearly polarized light L, can be allowed to pass through the receiving-side polarizing filter 32 (i.e., the change of the polarization state of the linearly polarized light L can be extracted), and the polarized light component can be guided to the image pickup device 35. As a result, the reflected image of the wafer 10, which is brought about by the polarized light component having the vibration direction substantially perpendicular to the linearly polarized light L and included in the regularly reflected light allowed to come from the wafer 10, is formed on the image pickup surface of the image pickup device 35.

Therefore, the image pickup device 35 photoelectrically converts the image (reflected image) of the surface of the wafer 10 formed on the image pickup surface to generate the image signal (digital image data). The image signal is outputted to the image processing unit 40 via the main controller 50. The image processing unit 40 generates the digital image of the wafer 10 (in the following description, the digital image of the wafer 10 based on the polarization is conveniently referred to as “polarized image”) based on the image signal of the wafer 10 outputted from the image pickup device 35. When the image processing unit 40 generates the polarized image of the wafer 10, the polarized image is sent to the inspection unit 42 via the main controller 50. The inspection unit 42 compares the polarized image data of the wafer 10 with the image data of the non-defective wafer previously stored in the storage unit 45 to inspect the presence or absence of the defect (abnormality) on the surface of the wafer 10. The inspection result and the polarized image of the wafer 10 obtained thereby, which are brought about by the image processing unit 40 and the inspection unit 42, are subjected to the output display by the image display apparatus 46, and the result and the image are stored in the storage unit 45. It is considered that the signal intensity (brightness value) of the reflected image of the non-defective wafer exhibits the highest signal intensity (brightness value). Therefore, for example, when the change (brightness change) of the signal intensity, which is obtained by making comparison with the non-defective wafer, is larger than a preset threshold value (allowable value), it is judged that the situation is “abnormal”. When the change of the signal intensity (brightness change) is smaller than the threshold value, it is judged that the situation is “normal”.

The signal intensity is the signal intensity corresponding to the light detected by the image pickup element of the image pickup device 35, including, for example, the reflection efficiency, the intensity ratio, and the energy ratio. It is also possible to perform the inspection based on the regularly reflected light allowed to come from the surface of the wafer 10 (hereinafter conveniently referred to as “regular reflection inspection”), without being limited to the diffraction inspection and the PER inspection described above. When the regular reflection inspection is performed, the image processing unit 40 generates the digital image (hereinafter conveniently referred to as “regular reflection image”) based on the regularly reflected light allowed to come from the surface of the wafer 10 to inspect the presence or absence of the defect (abnormality) on the surface of the wafer 10 based on the regular reflection image.

Further, the inspection unit 42 can determine the focus curve (curve to indicate the relationship between the focus offset amount and the signal intensity) based on the diffracted light of the exposure apparatus 101 by utilizing the image of the wafer subjected to the exposure and the development under the condition in which the focus offset amount of the exposure apparatus 101 is changed for each of the shots. When the focus offset amount, at which the signal intensity of the diffracted light is locally maximized, is determined for each minute area in one shot by utilizing the focus curve, it is possible to determine the inclination of the image plane of the mask pattern subjected to the projection exposure by using the exposure apparatus 101. In the case of the diffracted light, the focus offset amount, at which the signal intensity is locally maximized, provides the best focus, when the amount of space is not less than 10 while the amount of line is 1 in relation to the duty ratio of the line-and-space.

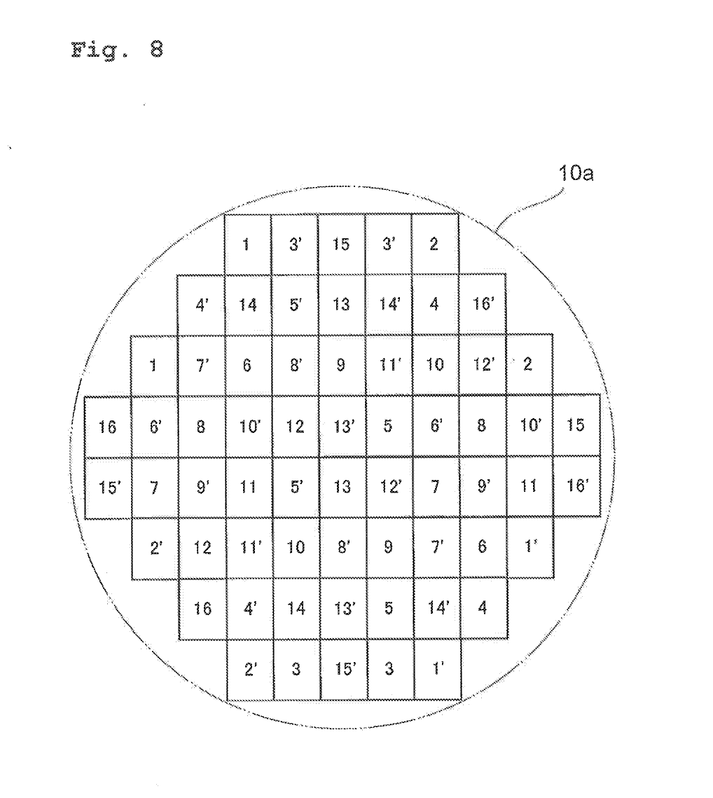

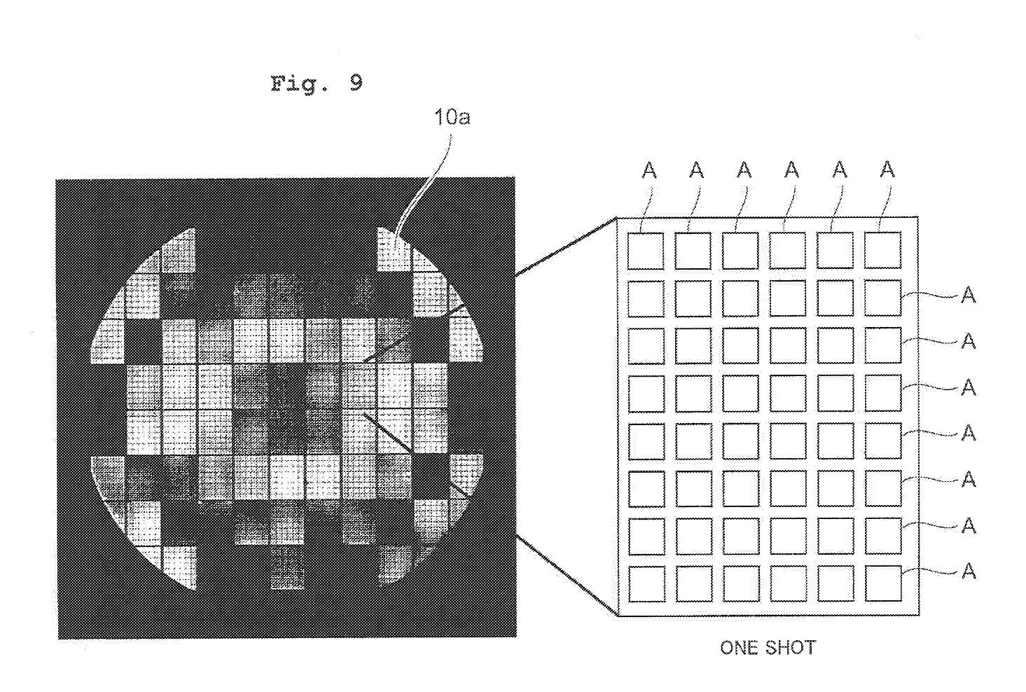

Accordingly, an explanation will be made with reference to a flow chart shown in FIG. 7 about a method for determining the inclination of the image plane of the mask pattern subjected to the projection exposure by using the exposure apparatus 101. At first, the focus offset amount (known) of the exposure apparatus 101 is changed to prepare the wafer on which the repeating pattern is formed (Step S101). In this procedure, as shown in FIG. 8, the focus offset amount is changed for each exposure shot, while the shots having the same focus offset amount (shots having the same number in FIG. 8) are set at different positions on the wafer to perform the exposure and the development. Such a wafer is hereinafter referred to as “condition-varied wafer 10a”.

In this procedure, the shots having the same focus offset amount are set at the different positions on the wafer, for example, in order to offset the influence of the difference in the resist condition generated between the central side and the outer circumferential side of the wafer and the so-called difference between the right and the left during the scanning exposure. The resist film (photoresist), which is formed on the wafer, is formed by the coating by means of the spin coat in many cases. In such a situation, a tendency appears such that the viscosity is raised as the solvent component is volatilized in accordance with the spread of the resist undiluted solution caused by the spin, and the film is thickened. Any difference arises in the resist condition between the central side and the outer circumferential side of the wafer. Further, the so-called the difference between the right and the left is the difference, for example, brought about between when the exposure is performed while moving the reticle in the X+ direction (wafer is moved in the X− direction) and when the exposure is performed while moving the reticle in the X− direction (wafer is moved in the X+ direction), assuming that the scanning direction is the X direction.

On the condition-varied wafer 10a, as shown in FIG. 8, for example, the focus offset amount is varied and allocated at sixteen levels of −175 nm to +200 nm in units of 25 nm. The levels (grades) of the focus offset amount, which are varied and allocated in units of 25 nm, are indicated by numbers (1 to 16) for the respective shots shown in FIG. 8. The shot, in which the focus offset amount is identical but the scanning direction is opposite, is affixed with “ ”. For example, as for the shots of the focus offset amount indicated by the number 12, the exposure, which is performed with the same focus offset amount, can be set at the four positions for one shot on the central side in the X+ direction of the reticle movement, one shot on the outer circumferential side in the X+ direction of the reticle movement, one shot on the central side in the X− direction of the reticle movement, and one shot on the outer circumferential side in the X− direction of the reticle movement. Further, for example, as for the shots of the focus offset amount indicated by the number 15, the exposure, which is performed with the same focus offset amount, can be set at the four positions for two shots on the outer circumferential side in the X+ direction of the reticle movement and two shots on the outer circumferential side in the X− direction of the reticle movement by using the point of symmetry of the center of the condition-varied wafer 10a. In the example shown in FIG. 8, the focus offset amounts are varied or allotted to the sixteen levels as described above, and the four shots are provided for each of the focus offset amounts to give the sixty-four shots in total which are set at the different positions (arranged in a scattered manner) so that the condition-varied wafer 10a is prepared.

It is also allowable that a plurality of condition-varied wafers are prepared to determine the focus curve. In this case, it is preferable the shot arrangement, which is provided for each of the focus offset amounts of the respective condition-varied wafers, is set so that the influence, which is exerted by any condition other than the focus offset amount, is offset.

When the condition-varied wafer 10a is prepared, the condition-varied wafer 10a is transported onto the stage 5 in the same manner as in the diffraction inspection described above (Step S102). Subsequently, the illumination light is radiated by the illumination system 20 onto the surface of the condition-varied wafer 10a in the same manner as in the diffraction inspection described above, and the image pickup device 35 photoelectrically converts the diffraction image of the condition-varied wafer 10a to generate the image signal so that the image signal is outputted to the image processing unit 40 (Step S103). In this procedure, the diffraction condition is determined for the condition-varied wafer 10a by utilizing the diffraction condition search or the information of the mask pattern subjected to the exposure, and the setting is performed in the same manner as in the diffraction inspection so that the diffracted light is obtained. The diffraction condition search refers to the following function. That is, the tilt angle of the stage 5 is changed in a stepwise manner within an angle range other than the regular reflection to obtain images at respective tilt angles so that the tilt angle, at which the image is brightened, i.e., the diffracted light is obtained, is determined.

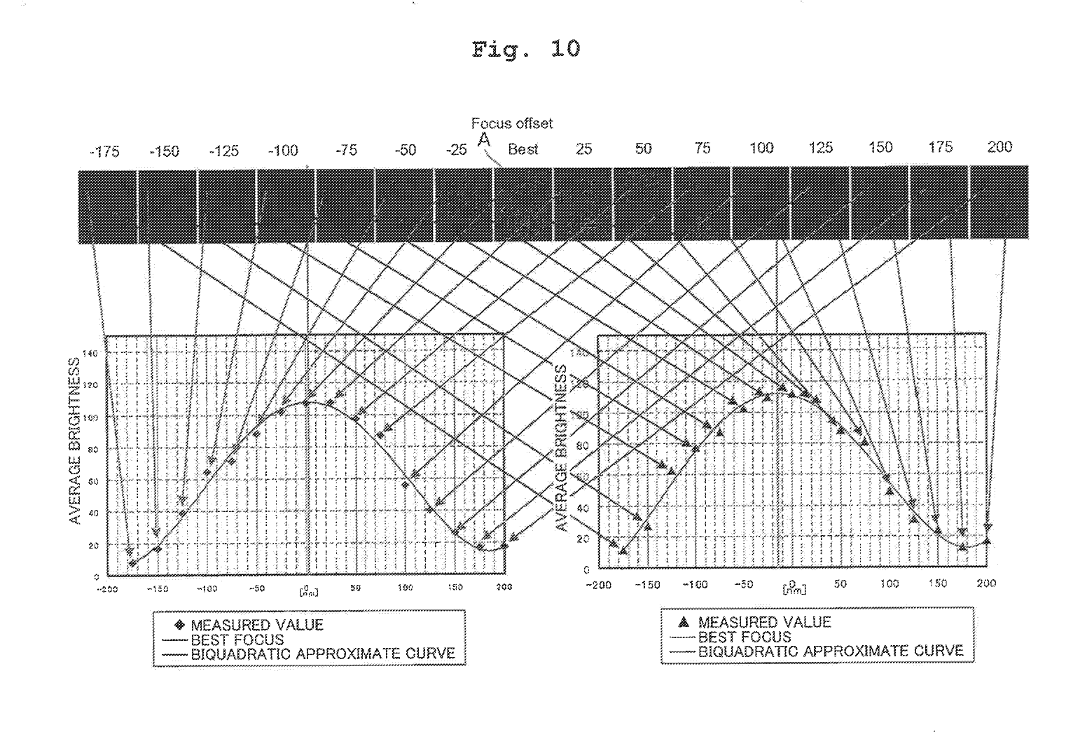

Subsequently, the image processing unit 40 generates the diffraction image of the condition-varied wafer 10a based on the image signal of the condition-varied wafer 10a inputted from the image pickup device 35 to average the signal intensities in pixel units for the respective shots having the same focus offset amount (in relation to the pixels of the corresponding portions of the respective shots) (Step S104). The portion, which is judged as the defect by the diffraction inspection, is excluded from the object of the averaging described above. Subsequently, the image processing unit 40 determines the average values of the signal intensities (hereinafter conveniently referred to as “average brightnesss”) respectively in a plurality of set areas A (areas surrounded by small rectangles) set in the shot as shown in FIG. 9 in relation to all of the shots obtained by the averaging (i.e. having the mutually different focus offset amounts) (Step S105). According to the processes as described until now, the average brightnesss are obtained for those provided respectively when the focus offset is gradated and allocated at the sixteen levels of −175 nm to +200 nm in units of 25 nm for the plurality of set areas A provided in each of the exposure shots respectively.

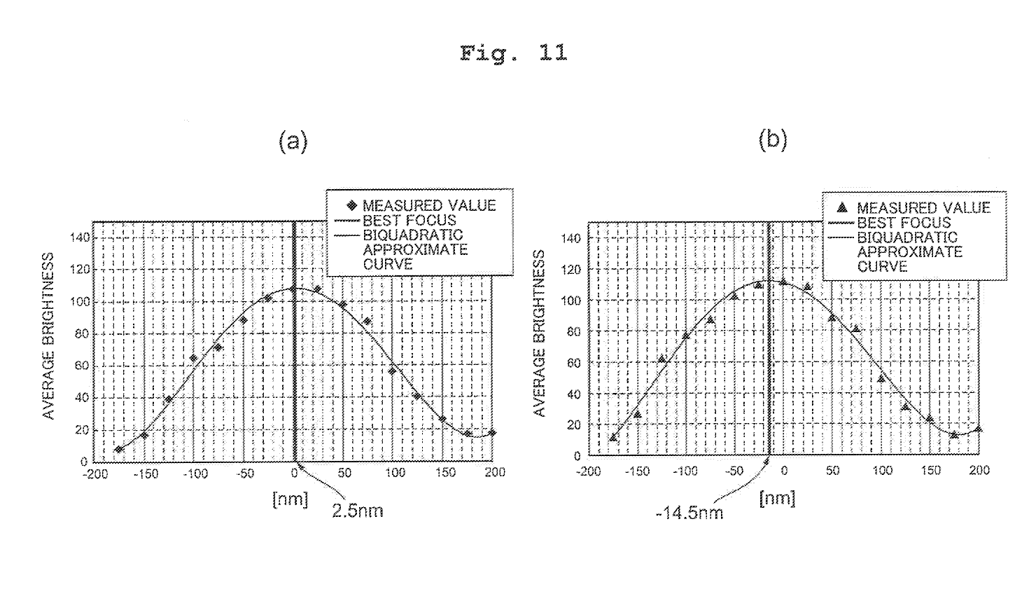

Subsequently, the image processing unit 40 sends the averaged data to the inspection unit 42 via the main controller 50. As shown in FIG. 10, the inspection unit 42 determines the graph to indicate the relationship between the average brightnesss in the set areas A at the identical positions in the respective shots (having the mutually different focus offset amounts) and the focus offset amounts corresponding thereto, i.e., the focus curve for the respective set areas A for which the average brightnesss are determined (Step S106). When the focus curves are determined, the inspection unit 42 determines the approximate curves of the focus curves respectively (Step S107). It is preferable to use an expression of the fourth degree (biquadratic expression) for the expression of the approximate curve. The focus curve, which is determined herein, is referred to as “reference focus curve”.

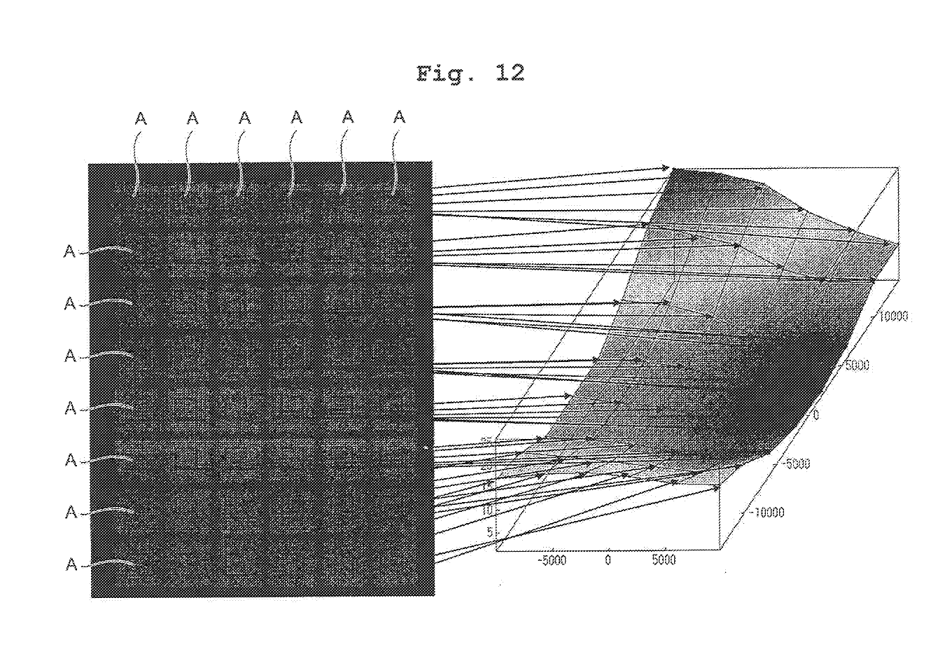

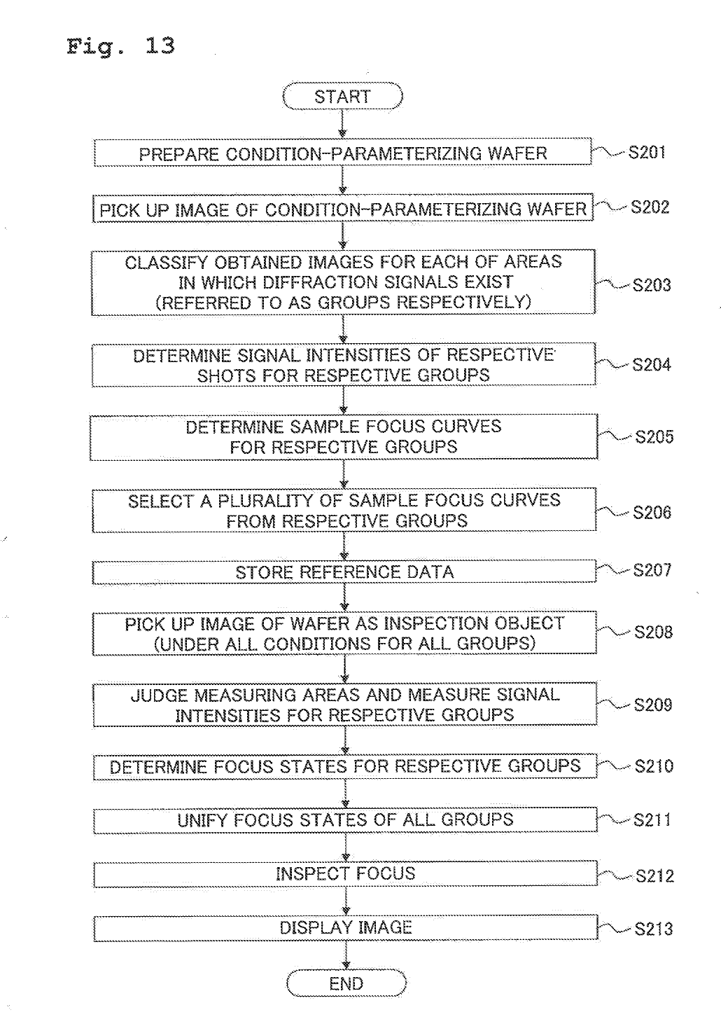

Subsequently, the inspection unit 42 determines the focus offset amount at which the average brightness is locally maximized (i.e., the focus offset amount is maximized in the range of −175 nm to +200 nm) for the approximate curve of the focus curve (Step S108). For example, in the case of the focus curve shown in FIG. 11A, the focus offset amount, at which the average brightness is locally maximized, is 2.5 nm. Further, for example, in the case of the focus curve shown in FIG. 11B, the focus offset amount, at which the average brightness is locally maximized, is −14.5 nm. In this procedure, the focus offset amount, at which the average brightness is locally maximized, is determined for each of the set areas A (Step S109). In this way, as shown in FIG. 12, it is possible to determine the distribution of the focus offset amounts at which the average brightnesss of the diffracted light are locally maximized in the shot.

According to the distribution of the focus offset amounts at which the average brightnesss of the diffracted light are locally maximized in the shot, it is possible to (approximately) determine the inclination of the focus offset amount (i.e., the amount of inclination of the image plane) in the long side direction of the slit (light) subjected to the exposure by the exposure apparatus 101 and the inclination of the focus offset amount in the scanning direction for the reticle stage and the wafer stage of the exposure apparatus 101 respectively. Even when the focus offset amount, at which the average brightness of the diffracted light is locally maximized, is not the best focus, when any approximate pattern portion in the shot is used, then the relationship between the focus offset amount and the average brightness of the diffracted light is provided in the same manner, and the inclination of the image plane resides in the relative positional relationship among the respective focusing points. Therefore, the inclination of the image plane is determined by determining the local maximum value of the average brightness. The inclination of the image plane determined as described above is converted into a parameter which is acceptable by the exposure apparatus 101 and which is exemplified, for example, by the field curvature ratio, the maximum/minimum value, and the inclination in the diagonal direction. After that, the parameter is outputted from the main controller 50 via the signal output unit 60 to the exposure apparatus 101, which is reflected to the exposure performed by the exposure apparatus 101. The inclination of the image plane, which is referred to in this embodiment, is the comprehensive or generic inclination of the image plane with respect to the photoresist layer on the wafer brought about by the image plane inclination of the projected image provided by the projection lens of the exposure apparatus 101 and the error of movement of the reticle stage and the wafer stage. In this way, the inspection unit 42 also has the measuring function.

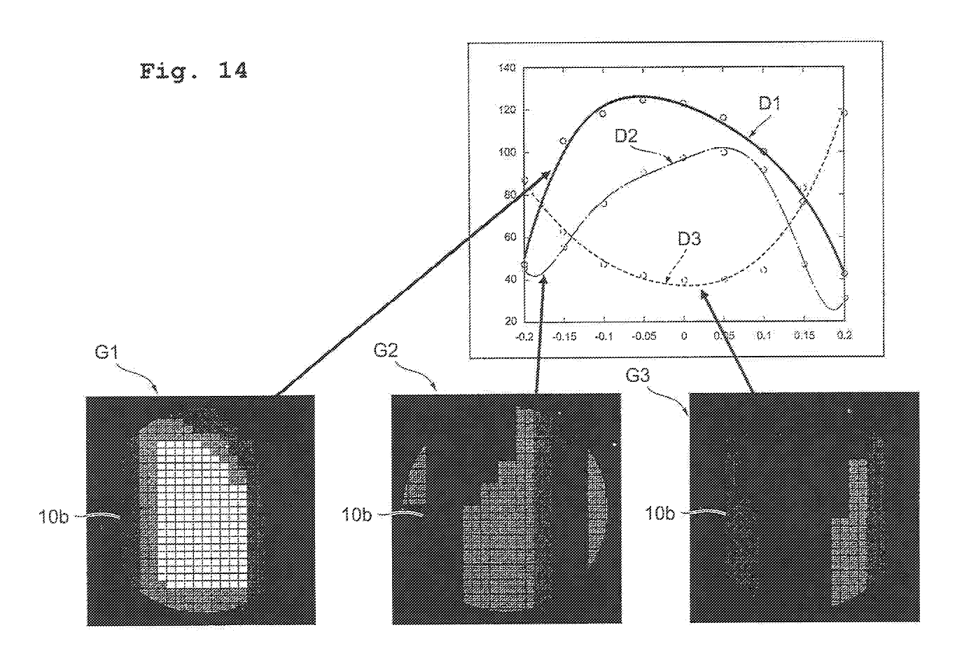

Further, the inspection unit 42 can determine the focus state during the exposure performed by the exposure apparatus 101 from the diffraction image of the wafer 10 as the inspection object, more specifically, the variation state of the focus of the exposure apparatus 101 with respect to the entire surface of the wafer 10. In view of the above, an explanation will be made with reference to a flow chart shown in FIG. 13 about a first embodiment of the method for determining the focus state during the exposure performed by the exposure apparatus 101.

At first, a condition-varied wafer 10b (so-called FEM wafer) is prepared, in which the repeating pattern is formed by changing the focus offset amount and the dose amount (exposure amount) of the exposure apparatus 101 in a matrix form (Step S201). The repeating pattern, which is formed in this procedure, is formed as the pattern that is the same as or equivalent to the repeating pattern 12 of the wafer 10 as the inspection object. That is, as shown in FIG. 4A, the repeating pattern is formed, which is constructed to include the first pattern area A composed of one type of repeating pattern or a plurality of types of repeating patterns and the second pattern area B having the repeating patterns constructed differently from the first pattern area A. When the condition-varied wafer 10b is prepared, for example, then the exposure shot, which is disposed at the center of the condition-varied wafer 10b, has the best focus and the best dose, the focus offset amount is changed for each of the exposure shots aligned in the lateral direction, and the dose amount is changed for each of the exposure shots aligned in the longitudinal direction so that the exposure is performed and the development is performed.

When the condition-varied wafer 10b is prepared in Step S201, the diffraction image of the condition-varied wafer 10b is acquired by image pickup (Step S202). In order to acquire the diffraction image of the condition-varied wafer 10b by image pickup, the condition-varied wafer 10b is firstly transported onto the stage 5 in the same manner as in the diffraction inspection described above. The illumination light is radiated by the illumination system 20 onto the surface of the condition-varied wafer 10b. The image pickup device 35 photoelectrically converts the diffraction image of the condition-varied wafer 10b to generate the image signal, and the image signal is outputted to the image processing unit 40. The image processing unit 40 generates the diffraction image of the condition-varied wafer 10b based on the image signal of the condition-varied wafer 10b inputted from the image pickup device 35. In this procedure, the diffraction image of the condition-varied wafer 10b is acquired by image pickup for a plurality of conditions determined by the combination of, for example, the orientation angle of the wafer, the illumination wavelength, the angle of incidence, and the outgoing angle, i.e., a plurality of diffraction conditions respectively.

When the repeating pattern of the condition-varied wafer 10b involves the under layer or involves any uneven underlying base, when the illumination light having a short wavelength (for example, 248 nm or 313 nm) is used, then any influence can be hardly exerted by the underlying base. When the illumination-side polarizing filter 26, in which the transmission axis is set in a predetermined orientation so that the s polarized light is obtained as the illumination light, is inserted into the optical path, any influence can be hardly exerted by the underlying base as well. Further, when the receiving-side polarizing filter 32, in which the transmission axis is set in a predetermined orientation so that only the diffracted light based on the s polarized light can be received, is inserted into the optical path, any influence can be hardly exerted by the underlying base as well.

When the diffraction images of the condition-varied wafer 10b are acquired by image pickup in Step S202, the image processing unit 40 classifies the plurality of diffraction images acquired by image pickup under the plurality of diffraction conditions respectively into those in which the diffraction signal of the first pattern area A in the repeating pattern is captured and those in which the diffraction signal of the second pattern area B is captured (Step S203). The pieces of position information of the first and second pattern areas A, B are previously known as the designed values. Therefore, the plurality of diffraction images can be classified by comparing the position information of the first and second pattern areas A, B with the position information in which the diffraction signal intensity is obtained in the diffraction image. The collection or group of the diffraction images in which the diffraction image of the first pattern area A is captured is referred to as “first image group G_{A}”, and the collection or group of the diffraction images in which the diffraction image of the second pattern area B is captured is referred to as “second image group G_{H}”.

When the diffraction images are classified into the respective image groups in Step S203, the image processing unit 40 determines the signal intensities of the respective shots for the respective diffraction images for the first image group G_{A} and the second image group G_{B} respectively (Step S204). In this procedure, the average value of the signal intensities is determined in relation to the shots in which the focus offset amount and the dose amount are identical, and the average value is used as the signal intensity of each of the shots. Accordingly, it is possible to eliminate the influence of the inclination of the image plane.

Subsequently, the image processing unit 40 sends the average value of the signal intensities of each shot to the inspection unit 42 via the main controller 50. The inspection unit 42 determines the graph which indicates the relationship between the signal intensity of each of the shots (mutually having the identical dose amount and the different focus offset amounts) and the focus offset amount corresponding thereto, i.e., the focus curve (hereinafter referred to as “sample focus curve” in order to be distinguished from the reference focus curve determined when the inclination of the image plane is measured), for the respective different dose amounts in relation to the first image group G_{A} and the second image group G_{B} respectively (Step S205). Accordingly, it is possible to determine the sample focus curves of the plurality of diffraction conditions in relation to the first and second image groups G_{A}, G_{B} respectively for the respective different dose amounts. Further, in this procedure, the approximate curves of the sample focus curves are determined respectively in the same manner as in the case of the reference focus curve described above. It is preferable to use an expression of the fourth degree (biquadratic expression) for the expression of the approximate curve.

Subsequently, the inspection unit 42 selects at least two types of sample focus curves to be used in order to determine the focus state during the exposure from the sample focus curves of the plurality of diffraction conditions in relation to the first image group G_{A} and the second image group G_{B} respectively (Step S206). That is, for example, three types of the reference sample focus curves are selected and decided for the first image group G_{A}, and three types of the reference sample focus curves are selected and decided for the second image group G_{B}, i.e., the reference sample focus curves of the six types in total are selected and decided. In order to select and decide the reference sample focus curves, the sample focus curves, which have the sensitivities to the change of the focus offset amount (have the high focus sensitivities), are firstly extracted from the plurality of sample focus curves. Subsequently, the sample focus curves, which have the weak (small) sensitivities to the change of the dose amount (have the low dose sensitivities) and which suffer less influence exerted by the underlying base change, are extracted from the sample focus curves having the high focus sensitivities. Further, at least two types (for example, three types) of the sample focus curves, in which the positions of the peaks or the bottoms of the curves (focus offset amounts) are different from each other, are selected and decided as the reference sample focus curves, from the sample focus curves which have the high focus sensitivities, which have the low dose sensitivities, and which suffer less influence exerted by the underlying base change.

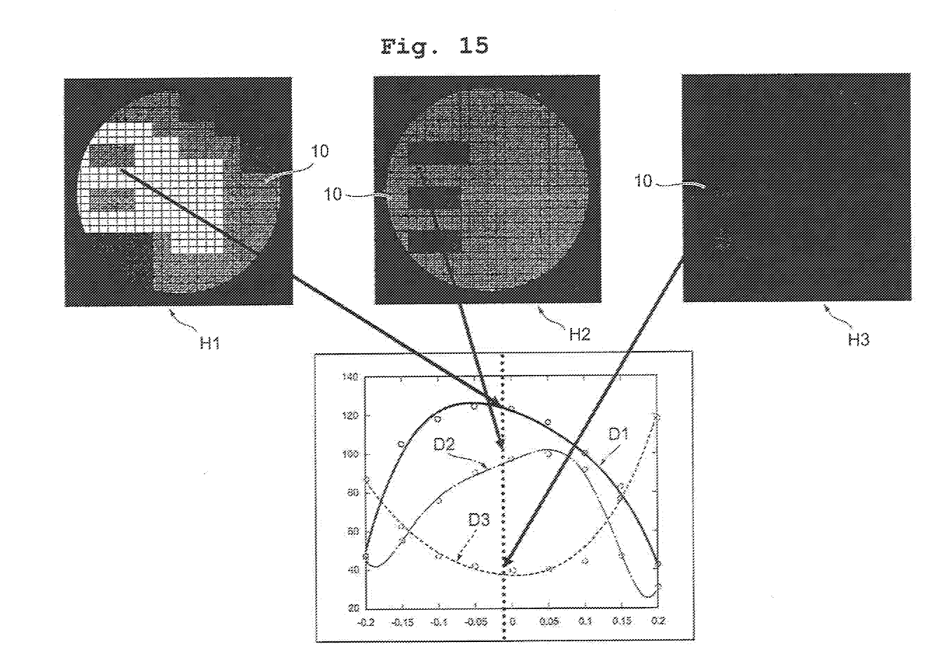

Accordingly, it is possible to determine the three types of reference sample focus curves to be used in order to determine the focus state during the exposure in relation to the first and second image groups G_{A}, G_{B} respectively. FIG. 14 shows examples of the reference sample focus curves determined as described above. FIG. 14 shows the diffraction image G1 with which the first reference sample focus curve D1 is obtained, the diffraction image G2 with which the second reference sample focus curve D2 is obtained, and the diffraction image G3 with which the third reference sample focus curve D3 is obtained respectively together with the three types of reference sample focus curves D1 to D3. The respective diffraction images G1 to G3 shown in FIG. 14 is the diffraction images of the condition-varied wafer 10b acquired by image pickup while changing the diffraction condition. Alternatively, the respective diffraction images can be acquired by image pickup by changing only the degree (order) of the diffracted light, while, for example, the pattern pitch and the illumination wavelength are identical.

When the reference sample focus curves are selected and decided in Step S206, then the image processing unit 40 outputs, to the storage unit 45, the data relevant to the expressions of the approximate curves of the reference sample focus curves decided for the first image group G_{A} and the second image group G_{B} respectively, as the reference data, and the image processing unit 40 allows the storage unit 45 to store the data (Step S207). The image processing unit 40 can output a data map to indicate the relationship between the focus offset amount determined from the expression of the approximate curve and the signal intensity as the reference data to the storage unit 45, and the image processing unit 40 can allow the storage unit 45 to store the data map, without being limited to the expression of the approximate curve of the reference sample focus curve.

When a plurality of exposure apparatuses 101 exist, the imaging characteristic can differ depending on the apparatus even when the exposure apparatus 101 is of the same type. Therefore, it is preferable that the reference data is determined for each of the plurality of exposure apparatuses and for each of the illumination conditions and the reference data is stored in the storage unit 45.

When the reference data concerning the reference sample focus curve is stored in the storage unit 45 in Step S207, the diffraction image of the wafer 10 as the inspection object is acquired by image pickup (Step S208). In this procedure, the diffraction images of the wafer 10 are acquired by image pickup respectively under the same diffraction conditions as those of the diffraction images with which the reference sample focus curves selected for the first image group G_{A} are obtained. Further, the diffraction images of the wafer 10 are acquired by image pickup respectively under the same diffraction conditions as those of the diffraction images with which the reference sample focus curves selected for the second image group G_{B} are obtained. For example, when the three types of reference sample focus curves are selected for the first and second image groups G_{A}, G_{B} respectively, i.e., when the six types of reference sample focus curves in total are selected, then the diffraction images of the wafer 10 are acquired by image pickup under the same six types of the diffraction conditions as those of the diffraction images with which the six types of the reference sample focus curves are obtained.

When the diffraction images of the wafer 10 as the inspection object are acquired by image pickup in Step S208, then the image processing unit 40 judges whether the areas corresponding to the respective pixels are the measuring areas in the shot from the signal intensity of each of the pixels of the diffraction image in relation to each of the groups of the first and second image groups G_{A}, G_{B}, and the pixels, which fall under, for example, the street, are excluded from the measuring object. The image processing unit 40 determines the average value of the signal intensities of a predetermined number of pixels for each of the diffraction images, and the average value is determined as the signal intensity of each shot (Step S209).

Subsequently, the image processing unit 40 sends the information of the average value of the signal intensities to the inspection unit 42 via the main controller 50. The inspection unit 42 determines the variation state of the focus of the exposure apparatus 101 with respect to the surface of the wafer 10 (hereinafter referred to as “focus state” as well) from the diffraction images of the wafer 10 as the inspection object for the respective groups of the first and second image groups G_{A}, G_{B} (Step S210). In this procedure, the focus offset amount of the exposure apparatus 101 with respect to the surface of the wafer 10 is determined for each of the predetermined pixels (in unit of one pixel or a plurality of pixels) from the signal intensity of the diffraction image of the wafer 10 by utilizing the reference data stored in the storage unit 45 (i.e., the expression of the approximate curve of the reference sample focus curve or the data map). The focus state of the measuring point of the area A shown in FIG. 4 is determined from the first pattern area A, and the focus state of the measuring point of the area B shown in FIG. 4 is determined from the second pattern area B.

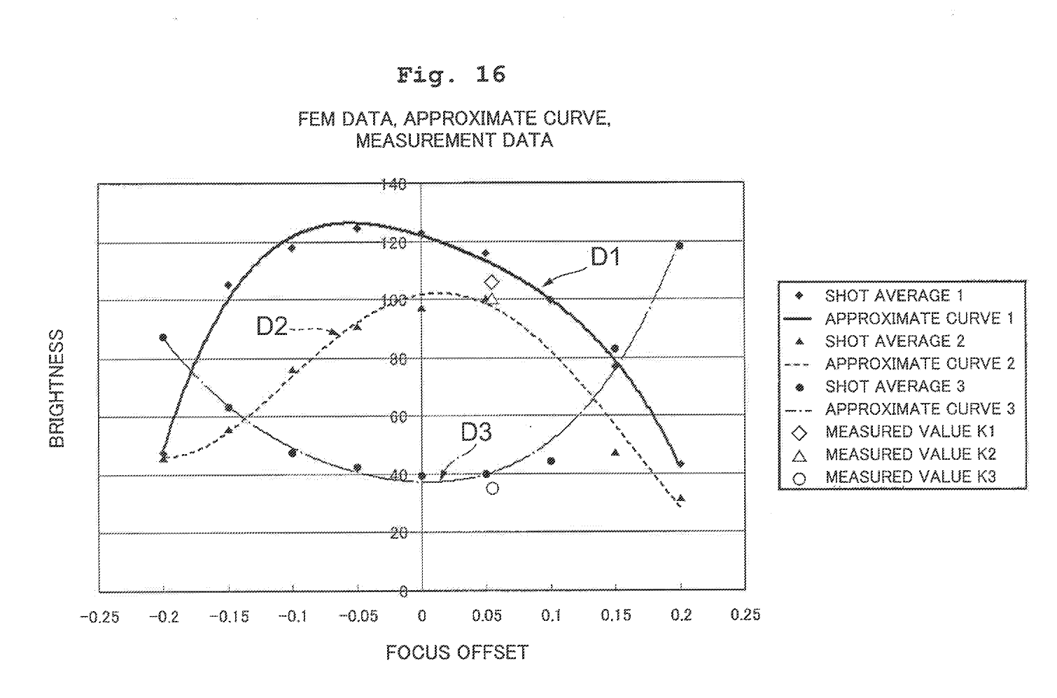

When the focus offset amount is determined, the expressions of the approximate curves of the reference sample focus curves (or the data map), which correspond to the three types of the diffraction conditions respectively, are stored in the storage unit 45. Therefore, it is possible to determine the focus offset amounts respectively for the respective predetermined pixels from the signal intensities of the diffraction images of the wafer 10 acquired by image pickup under the same condition respectively. Since the focus curve is the curve, a plurality of candidates (or one candidate depending on the condition) of the focus offset amount are calculated from one signal intensity of the diffraction image. In relation thereto, when the three types of reference sample focus curves D1 to D3, in which the positions of the peaks or the bottoms of the curves (focus offset amounts) are different from each other, are used, one focus offset amount to be calculated is decided as shown in FIG. 15. For example, the focus offset amount is determined, in which the sum of squares of differences between the signal intensity under each diffraction condition and the approximate curve corresponding to the condition is minimized. Three types of reference sample focus curves D1 to D3 can be prepared for respective different dose amounts, and the focus offset amount, which is obtained at such a dose amount that the sum of squares of differences is minimized, can be adopted. Alternatively, it is also allowable that the weighting is performed (degree of contribution is enhanced) with respect to the signal intensity under the condition in which the inclination of the curve is relatively large (i.e., the sensitivity to the focus change is relatively high). Further, as for any pixel in which the minimum value of the sum of squares of differences exceeds a predetermined value, it is also appropriate that any result thereof is not adopted while being regarded as an abnormal value.

Accordingly, it is possible to calculate the focus offset amount, and it is possible to measure the variation state of the focus of the exposure apparatus 101 with respect to the surface of the wafer 10. FIG. 15 shows a diffraction image H1 of the wafer 10 picked up under the diffraction condition in which the first reference sample focus curve D1 is obtained, a diffraction image H2 of the wafer 10 picked up under the diffraction condition in which the second reference sample focus curve D2 is obtained, and a diffraction image H3 of the wafer 10 picked up under the diffraction condition in which the third reference sample focus curve D3 is obtained respectively, together with the three types of the reference sample focus curves D1 to D3.

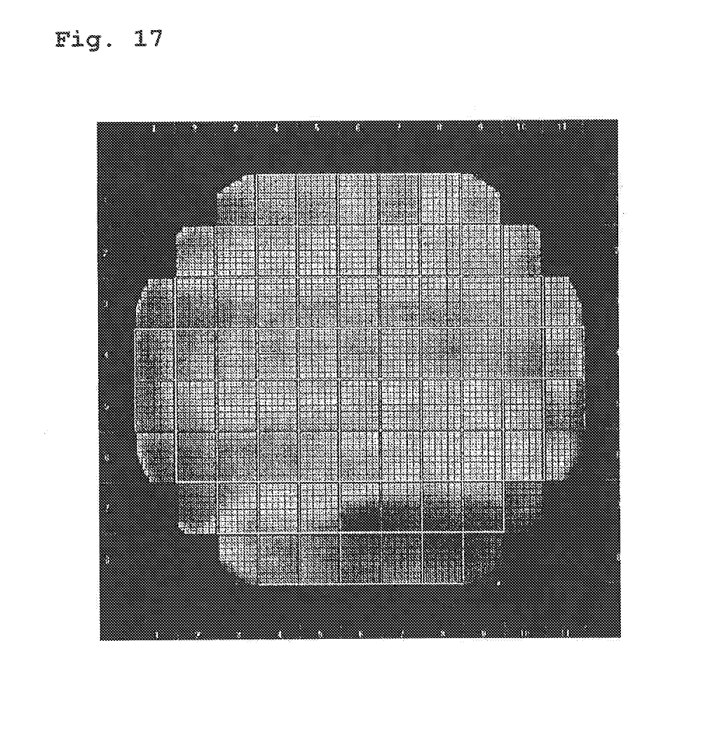

FIG. 16 shows a relationship between measured values of respective signal intensities (first signal intensity K1, second signal intensity K2, and third signal intensity K3) at a focus offset amount at which the sum of squares of differences is minimized and the reference sample focus curves D1 to D3. As shown in FIG. 16, it is appreciated that the degree of coincidence is high between the first detection signal (first signal intensity K1) corresponding to the diffracted light based on the first diffraction condition from the repeating pattern 12 detected by the image pickup device 35 and the first reference data corresponding to the diffraction condition (first reference sample focus curve D1), the degree of coincidence is high between the second detection signal (second signal intensity K2) corresponding to the diffracted light based on the second diffraction condition from the repeating pattern 12 and the second reference data corresponding to the diffraction condition (second reference sample focus curve D2), and the degree of coincidence is high between the third detection signal (third signal intensity K3) corresponding to the diffracted light based on the third diffraction condition from the repeating pattern 12 and the third reference data corresponding to the diffraction condition (third reference sample focus curve D3).

When the variation states of the focus of the exposure apparatus 101 are determined for the respective groups of the first and second image groups G_{A}, G_{B} in Step S210, the variation states are unified to determine the variation states of the focus of the exposure apparatus 101 at all of the measuring points of the repeating pattern 12 (Step S211). In this procedure, for example, any minute gain of the focus state and the difference in the offset amount exist between the focus state of the first pattern area A and the focus state of the second pattern area B in some cases. Therefore, in such a situation, the minute difference can be adjusted. For example, it is also allowable that the focus states at all of the measuring points shown in FIG. 4B can be smoothened.

When the focus offset amounts are determined for the respective predetermined pixels in relation to all of the measuring points of the repeating pattern 12 (on the entire surface of the wafer 10) in Step S211, the inspection unit 42 inspects whether or not the determined focus offset amount is abnormal (Step S212). In this procedure, for example, the inspection unit 42 judges that the determined focus offset amount is normal when the determined focus offset amount is within a predetermined threshold value range. The inspection unit 42 judges that the determined focus offset amount is abnormal when the determined focus offset amount is without the predetermined threshold value range.

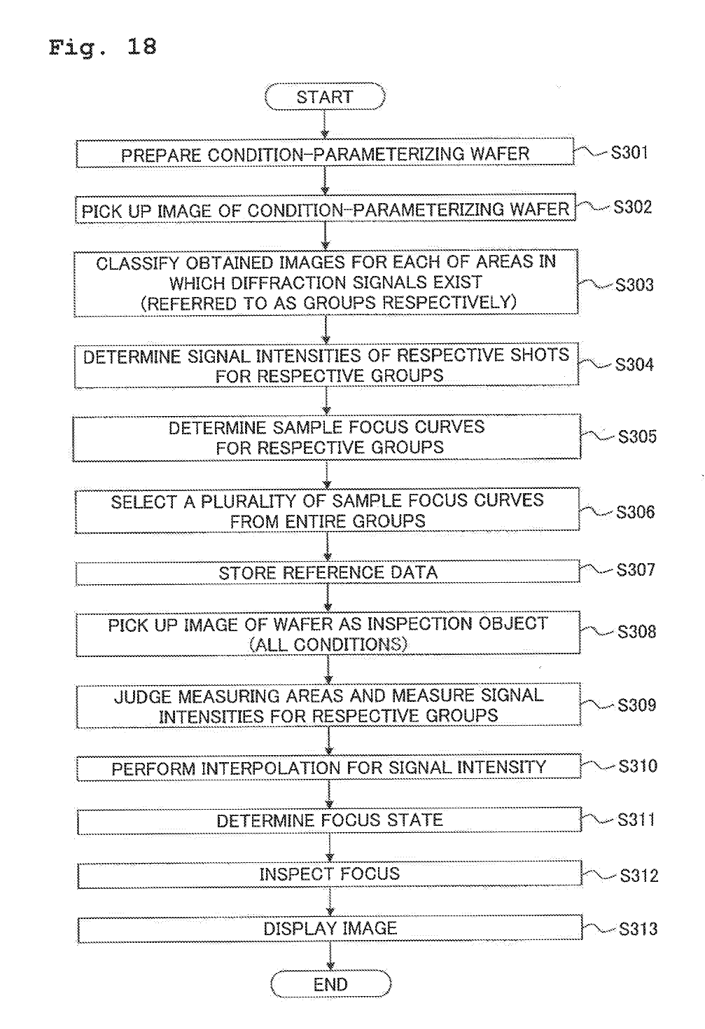

When the presence or absence of the abnormality of the focus offset amount is inspected in Step S212, then the image processing unit 40 generates the image of the wafer 10 in which the determined focus offset amounts are converted into the signal intensities at the respective concerning pixels, and the image is displayed on the image display apparatus 46 together with, for example, the inspection result of the focus offset amount (Step S213). Further, the image of the concerning wafer 10 and the inspection result are stored in the storage unit 45. The image display apparatus 46 is not limited to the apparatus provided for the surface inspection apparatus 1. It is also allowable to use an image display apparatus which is provided outside the inspection apparatus (for example, in a control room for the semiconductor production line) and which is connected. In this context, FIG. 17 shows an example of the image of the wafer 10 obtained by converting the focus offset amounts into the signal intensities. The image shown in FIG. 17 is not limited to the black-and-white image. It is also allowable that a color image is displayed.

In Step S206, for example, when the six types of the reference sample focus curves are selected in total for the first and second image groups G_{A}, G_{B}, one of the diffraction conditions of the first pattern area A is accidentally coincident with one of the diffraction conditions of the second pattern area B in some cases. In such a situation, it is appropriate that the diffraction images of the wafer 10 are acquired by image pickup under the five types of diffraction conditions including the coincident diffraction condition in Step S208.

As described above, according to the surface inspection apparatus 1 of this embodiment, the measuring areas are judged and the signal intensities are measured for the respective groups in the first and second image groups G_{A}, G_{B} to determine the variation states of the focus of the exposure apparatus 101. The variation states of the focus of the exposure apparatus 101, which are determined for the respective groups, are unified to determine the variation states of the focus of the exposure apparatus 101 at all of the measuring points of the repeating pattern 12 (on the entire surface of the wafer 10). Accordingly, even in the case of the wafer 10 for the logic device in which the areal size of the pattern formed on the wafer 10 is small and a large number of areas having differently constructed patterns exist, it is possible to determine the focus state during the exposure based on the image of the wafer 10 subjected to the exposure with the mask pattern to be used for the actual exposure. Therefore, any considerable time is not required for the condition setting operation for the parameter required for the measurement to be performed with the mask for exclusive use, unlike the case in which the mask substrate for exclusive use is used. Therefore, it is possible to measure the focus state during the exposure in a short period of time. Further, the pattern to be used for the actual device can be used without using any mask pattern for exclusive use. Furthermore, the illumination condition for the exposure apparatus 101 is not restricted as well. Therefore, it is possible to accurately measure the focus state during the exposure of the pattern used for the actual device.

In this procedure, the three types of reference data (reference sample focus curves D1 to D3) are used, in which the positions of the peaks or the bottoms of the curves (focus offset amounts) are different from each other (i.e., the way of change of the detection signal differs with respect to the change of the focus). Thus, one calculated focus offset amount is decided as described above. Therefore, it is possible to more accurately measure the focus state during the exposure.

Further, the three types of reference data (reference sample focus curves D1 to D3), in which the sensitivity is given with respect to the focus change and the sensitivity is weak with respect to the change of the dose amount (exposure amount), are used, and the sensitivity with respect to the focus change (change of the detection signal) is larger than the sensitivity with respect to the change of the dose amount (change of the detection signal). Therefore, it is possible to exclude the influence exerted by the change of the dose amount, and it is possible to more accurately measure the focus state during the exposure.

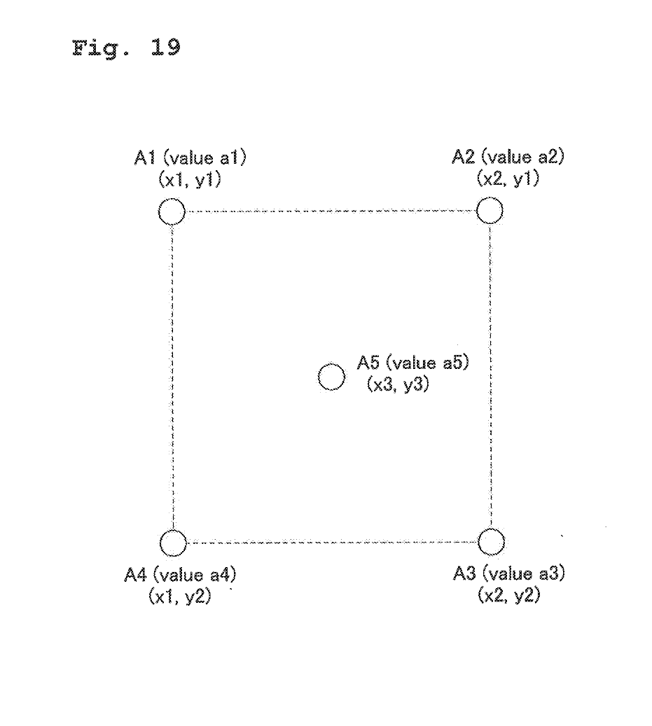

Next, an explanation will be made with reference to a flow chart shown in FIG. 18 about a second embodiment of the method for determining the focus state during the exposure performed by the exposure apparatus 101. In the meantime, in the first embodiment, the plurality of diffraction conditions, which are required to measure the focus state, are determined (can be determined) for each of the first and second pattern areas A, B. However, in the case of the single one of each of the first and second pattern areas A, B, it is sometimes impossible to determine the plurality of diffraction conditions required for the measurement, i.e., the plurality of diffraction conditions in which the focus sensitivity is high, the dose sensitivity is low, the influence of the underlying base change is small, and the positions of the peaks or the bottoms are different. For example, when the pattern densities of the first and second pattern areas A, B are sparse respectively and/or when the pattern area is composed of the repetition of one type of simple pattern, it is sometimes impossible to determine the plurality of diffraction conditions required to measure the focus state in each of the first and second pattern areas A, B on account of the pattern shape. In the second embodiment, an explanation will be made about a method for determining the focus state during the exposure in such a situation. It is assumed that the arrangement structure of the repeating pattern is the same as or equivalent to that shown in FIG. 4 used for the explanation of the first embodiment, and reference is made to the same drawing of FIG. 4.

As shown in FIG. 18, Steps S301 to S305 in the second embodiment are the same as Steps S201 to S205 of the first embodiment described above as shown in FIG. 13. That is, a condition-varied wafer 10b (see FIG. 14) is prepared (Step S301), and the condition-varied wafer 10b is subjected to the image pickup under various diffraction conditions (Step S302). A plurality of obtained diffraction images are classified into those which capture the diffraction signal of the first pattern area A and those which capture the diffraction signal of the second pattern area B (Step S303). The signal intensity is measured for each of the diffraction images in relation to each of the first image group G_{A} and the second image group G_{B} to determine the shot average value (Step S304) and determine the sample focus curve (Step S305).

Subsequently, the inspection unit 42 selects at least one set (at least one type from the first image group G_{A} and one type from the second image group G_{B}) of the reference sample focus curves to be used in order to determine the focus state during the exposure from the plurality of sample focus curves in relation to the first image group G_{A} and the second image group G_{B} (Step S306). For example, one type in the first image group G_{A} and two types in the second image group G_{B}, i.e., three types in total of the reference sample focus curves are selected and decided. In order to select and decide the reference sample focus curves, in the same manner as in the embodiment described above, the sample focus curves, which have the sensitivities to the change of the focus offset amount (have the high focus sensitivities), are firstly extracted from the plurality of sample focus curves. Subsequently, the sample focus curves, which have the weak sensitivities to the change of the dose amount (have the low dose sensitivities) and which suffer less influence exerted by the underlying base change, are extracted from the sample focus curves having the high focus sensitivities. Further, the sample focus curves, in which the positions of the peaks or the bottoms of the curves (focus offset amounts) are different from each other, are selected and decided as the reference sample focus curves from the sample focus curves which have the high focus sensitivities, which have the low dose sensitivities, and which suffer less influence exerted by the underlying base change.

When the reference sample focus curves are selected and decided in Step S306, then the image processing unit 40 outputs, as the reference data, the data concerning the expressions of the approximate curves of the reference sample focus curves decided for the first image group G_{A} and the second image group G_{B} respectively to the storage unit 45, and the image processing unit 40 allows the storage unit 45 to store the data (Step S307). The image processing unit 40 can output a data map to indicate the relationship between the focus offset amount determined from the expression of the approximate curve and the signal intensity as the reference data to the storage unit 45, and the image processing unit 40 can allow the storage unit 45 to store the data map, without being limited to the expression of the approximate curve of the reference sample focus curve.

When a plurality of exposure apparatuses 101 exist, the imaging characteristic can differ depending on the apparatus even when the exposure apparatus 101 is of the same type. Therefore, it is preferable that the reference data is determined for each of the plurality of exposure apparatuses and for each of the illumination conditions and the reference data is stored in the storage unit 45.

When the reference data concerning the reference sample focus curve is stored in the storage unit 45 in Step S307, the diffraction image of the wafer 10 as the inspection object is acquired by image pickup (Step S308). In this procedure, the diffraction images of the wafer 10 are acquired by image pickup respectively under the same diffraction conditions as those of the diffraction images with which the reference sample focus curves selected for the first image group G_{A} are obtained. Further, the diffraction images of the wafer 10 are acquired by image pickup respectively under the same diffraction conditions as those of the diffraction images with which the reference sample focus curves selected for the second image group G_{B} are obtained. For example, when the one type of reference sample focus curve is selected for the first image group G_{A}, and the two types of reference sample focus curves are selected for the second image groups G_{B}, i.e., when the three types of reference sample focus curves in total are selected, then the diffraction images of the wafer 10 are acquired by image pickup under the same three types of the diffraction conditions as those of the diffraction images with which the three types of the reference sample focus curves are obtained.

When the diffraction images of the wafer 10 as the inspection object are acquired by image pickup in Step S308, then the image processing unit 40 judges whether the areas corresponding to the respective pixels are the measuring areas in the shot from the signal intensity of each of the pixels of the diffraction image in relation to each of the groups of the first and second image groups G_{A}, G_{B}, and the pixels, which fall under, for example, the street, are excluded from the measuring object. The image processing unit 40 determines the average value of the signal intensities at the measuring point for each of the diffraction images, and the average value is determined as the signal intensity of each of the measuring points (Step S309).

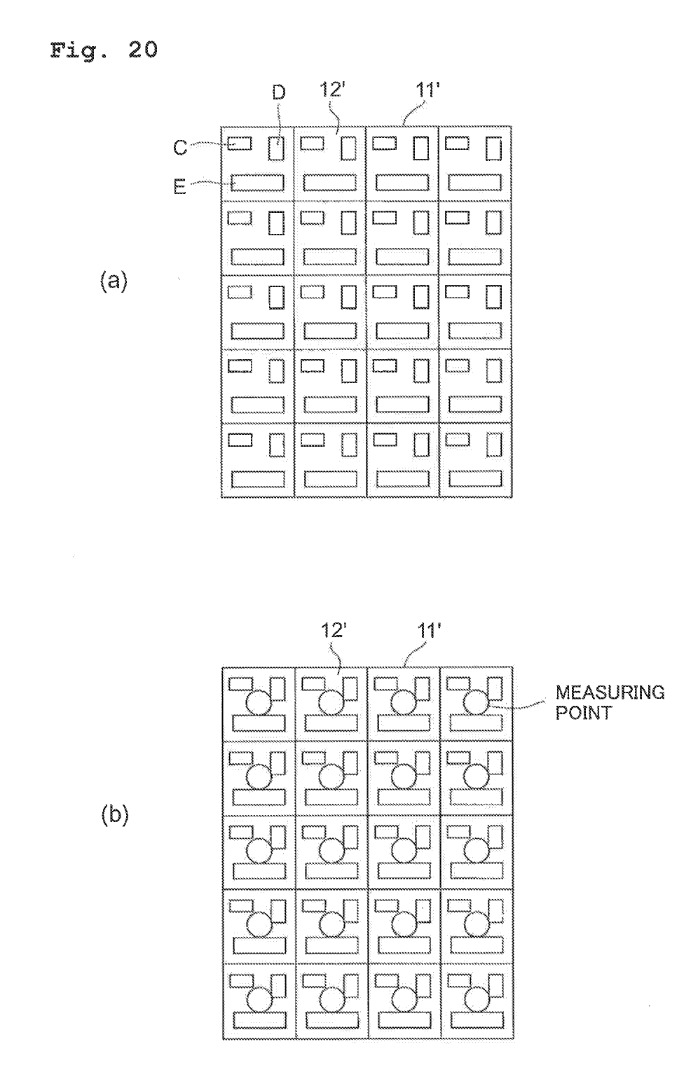

Subsequently, the image processing unit 40 determines the signal intensities by means of the interpolation for the measuring points at which any signal intensity is not obtained for each of the all diffraction conditions under which the focus offsets are to be obtained (the points or positions having no pattern for generating the diffracted light under the concerning diffraction condition) (Step S310). In the case of the diffraction image picked up under the diffraction condition selected from the first image group G_{A}, only the first pattern areas A shown in FIG. 4A provide bright images, and the other portions including the second pattern areas B are dark. Therefore, as for the measuring points shown in FIG. 4B, the signal intensities are obtained for those disposed in the first pattern areas A, but any signal intensity is not obtained for those disposed in the second pattern areas B. Therefore, as for the measuring points disposed in the second pattern areas B, the signal intensities are determined by means of the interpolation from the signal intensities obtained for the measuring points in the first pattern areas A disposed around the concerning measuring points. Several methods, which are generally known, are available for the interpolation. It is allowable to use any interpolation method. For example, the nearest neighbor interpolation is the simplest interpolation, wherein the value of the nearest point for which the measured value exists is regarded as the value of the point to be determined. In the linear interpolation, the value of the point to be determined is calculated by the linear calculation from a plurality of points disposed therearound. An example of the calculation formula of the linear interpolation is shown in Numerical Expression (2). Numerical Expression (2) is an example of the calculation formula to be used when four points A1 to A4 disposed around a point A5 to be determined, for which the measured values exist, are in a positional relationship of four corners of a rectangle (see FIG. 19). In any case other than the above, it is possible to perform the interpolation by means of the linear calculation. Other than the above, various methods are available, including, for example, the cubic convolution interpolation. It is possible to improve the interpolation accuracy by considering the image plane inclination of the entire shot when the interpolation is performed.

$$A 5 = \frac{x 2 - x 3}{x 2 - x 1} ( \begin{matrix}\frac{y 2 - y 3}{y 2 - y 1} a 1 + \\ \frac{y 3 - y 1}{y 2 - y 1} a 4\end{matrix} ) + \frac{x 3 - x 1}{x 2 - x 1} ( \begin{matrix}\frac{y 2 - y 3}{y 2 - y 1} a 2 + \\ \frac{y 3 - y 1}{y 2 - y 1} a 3\end{matrix} ) \qquad ( 2 )$$

Subsequently, the image processing unit 40 sends the information of the average value of the signal intensities and the signal intensities determined by the interpolation to the inspection unit 42 via the main controller 50. The inspection unit 42 determines the variation state of the focus of the exposure apparatus 101 with respect to the surface of the wafer 10 (hereinafter referred to as “focus state” as well) from the diffraction image (signal intensities) of the wafer 10 as the inspection object and the signal intensities determined by the interpolation (Step S311). In this procedure, the focus offset amount of the exposure apparatus 101 with respect to the surface of the wafer 10 is determined for each of the measuring points from the signal intensity of the diffraction image of the wafer 10 and the signal intensity determined by the interpolation by utilizing the reference data stored in the storage unit 45 (i.e., the expression of the approximate curve of the reference sample focus curve or the data map). When the measuring point is not constructed by a plurality of pixels but the measuring point is constructed by one pixel, then the focus offset is determined for each of the pixels.

When the focus offset amounts of all of the measuring points of the repeating pattern 12 are determined in Step S311, the inspection unit 42 inspects whether or not the determined focus offset amount is abnormal (Step S312). In this procedure, for example, the inspection unit 42 judges that the determined focus offset amount is normal when the determined focus offset amount is within a predetermined threshold value range. The inspection unit 42 judges that the determined focus offset amount is abnormal when the determined focus offset amount is without the predetermined threshold value range.

When the presence or absence of the abnormality of the focus offset amount is inspected in Step S312, then the image processing unit 40 generates the image of the wafer 10 (see FIG. 17) in which the focus offset amounts determined for the respective measuring points are converted into the signal intensities at the respective measuring points, and the image is displayed on the image display apparatus 46 together with, for example, the inspection result of the focus offset amount (Step S313). Further, the image of the concerning wafer 10 and the inspection result are stored in the storage unit 45.

In relation to the interpolation in Step S310, when the value of the measuring point in the vicinity of the boundary of the shot is determined, there are a method in which the value of the measuring point exceeding the shot is not used and the interpolation is performed by using only the data of the neighboring points in the shot and a method in which the measuring point exceeding the shot is used. It is also allowable to properly use, for example, the former when the variation in the shot is dominantly caused or the latter when the variation on the entire wafer surface is dominantly caused, in view of the problem of the focus state intended to be measured.

As described above, according to the surface inspection apparatus 1 of the second embodiment, the measuring areas are judged and the signal intensities are measured for the respective groups of the first and second image groups G_{A}, G_{B}, wherein the signal intensities of the portions, which are lacking for the determination of the focus state, are determined by means of the interpolation. Further, the variation states of the focus of the exposure apparatus 101, which are provided at all of the measuring points of the repeating pattern 12 (on the entire surface of the wafer 10), are determined from the diffraction image of the wafer 10 as the inspection object (signal intensities) and the signal intensities determined by the interpolation. Accordingly, even in the case of the wafer 10 for the logic device in which the areal size of the pattern formed on the wafer 10 is small and a large number of areas having differently constructed patterns exist, it is possible to determine the focus state during the exposure based on the image of the wafer 10 exposed with the mask pattern to be used for the actual exposure. Therefore, any considerable time is not required for the condition setting operation for the parameter required for the measurement to be performed with the mask for exclusive use, i.e., the operation such as the test exposure and the line width measurement, unlike the case in which the mask (reticle) for exclusive use is used. Therefore, it is possible to measure the focus state during the exposure in a short period of time. The pattern to be used for the actual device can be used without using any mask pattern for exclusive use. Further, the illumination condition of the exposure apparatus 101 is not restricted as well. Therefore, it is possible to accurately measure the focus state during the exposure.

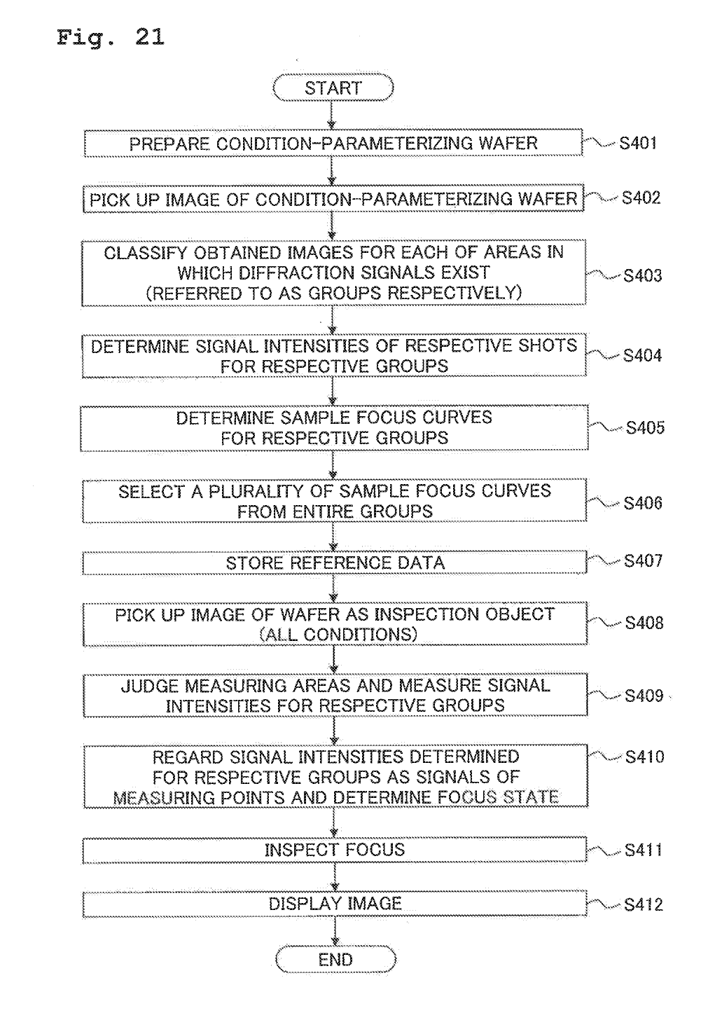

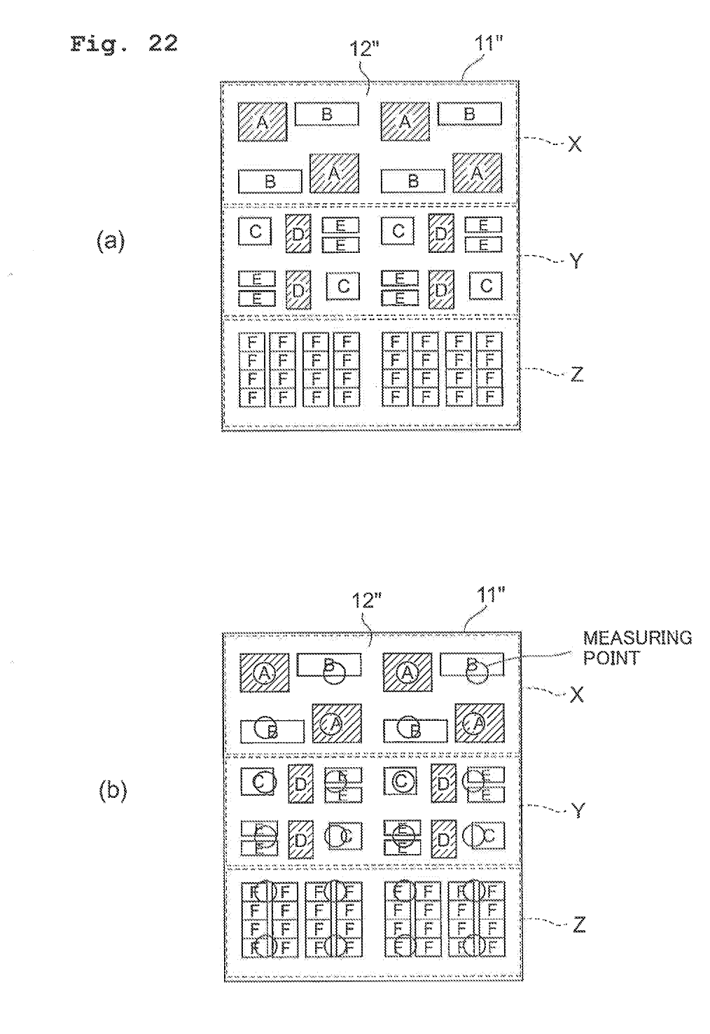

Next, an explanation will be made with reference to FIGS. 20 and 21 about a third embodiment of the method for determining the focus state during the exposure performed by the exposure apparatus 101. FIG. 20 shows an arrangement structure different from that of the embodiment described above, of the pattern on the surface of the wafer 10. In the third embodiment, a plurality of chip areas 11′, in which 4×5 pieces (20 pieces in total) of small chips are arranged while being aligned, are arranged in one shot as shown in FIG. 20, without adopting an arrangement of 1 chip/1 shot on the surface of the wafer 10. A repeating pattern 12′, which is formed in the chip area 11′, is constructed to include a third pattern area C, a fourth pattern area D, and a fifth pattern area E having repeating patterns constructed differently from each other. The wafer 10 is also a wafer for a logic device in which the areal size of the pattern formed on the surface is small and a plurality of areas having differently constructed patterns exist. It is assumed that the third to fifth pattern areas C to E reside in the pattern construction such that a plurality of diffraction conditions required for the focus measurement cannot be selected by using the third to fifth pattern areas C to E singly respectively, and the focus measurement can be performed when one type of the diffraction condition is selected for each of the third to fifth pattern areas C to E, i.e., when three types of the diffraction conditions in total are selected. In FIG. 20B, the focus measuring points are indicated by circles.

As shown in FIG. 21, Steps S401 to S405 in the third embodiment are the same as Steps S201 to S205 of the first embodiment described above as shown in FIG. 13. That is, a condition-varied wafer 10b (see FIG. 14) is prepared (Step S401), and the condition-varied wafer 10b is subjected to the image pickup under various diffraction conditions (Step S402). A plurality of obtained diffraction images are classified into those which capture the diffraction signal of the third pattern area C, those which capture the diffraction signal of the fourth pattern area D, and those which capture the diffraction signal of the fifth pattern area E (Step S403). The signal intensity is measured for each of the diffraction images in relation to each of the third image group G_{C}, the fourth image group G_{D}, and the fifth image group G_{E} to determine the shot average value (Step S404) and determine the sample focus curve (Step S405).

Subsequently, the inspection unit 42 selects at least one set (at least one type from the third image group G_{C}, one type from the fourth image group G_{D}, and one type from the fifth image group G_{E}) of the reference sample focus curves to be used in order to determine the focus state during the exposure from the plurality of sample focus curves in relation to the third to fifth image groups G_{C} to G_{E} (Step S406). For example, one type in the third image group G_{C}, one type in the fourth image group G_{D}, and one type in the fifth image group G_{E}, i.e., three types in total of the reference sample focus curves are selected and decided. In order to select and decide the reference sample focus curves, in the same manner as in the embodiment described above, the sample focus curves, which have the sensitivities to the change of the focus offset amount (have the high focus sensitivities), are firstly extracted from the plurality of sample focus curves. Subsequently, the sample focus curves, which have the weak sensitivities to the change of the dose amount (have the low dose sensitivities) and which suffer less influence exerted by the underlying base change, are extracted from the sample focus curves having the high focus sensitivities. Further, the sample focus curves, in which the positions of the peaks or the bottoms of the curves (focus offset amounts) are different from each other, are selected and decided as the reference sample focus curves from the sample focus curves which have the high focus sensitivities, which have the low dose sensitivities, and which suffer less influence exerted by the underlying base change.

When the reference sample focus curves are selected and decided in Step S406, then the image processing unit 40 outputs, as the reference data, the data concerning the expressions of the approximate curves of the reference sample focus curves decided for the third to fifth image groups G_{C} to G_{E} respectively to the storage unit 45, and the image processing unit 40 allows the storage unit 45 to store the data (Step S407). The image processing unit 40 can output a data map to indicate the relationship between the focus offset amount determined from the expression of the approximate curve and the signal intensity as the reference data to the storage unit 45, and the image processing unit 40 can allow the storage unit 45 to store the data map, without being limited to the expression of the approximate curve of the reference sample focus curve.

When a plurality of exposure apparatuses 101 exist, the imaging characteristic can differ depending on the apparatus even when the exposure apparatus 101 is of the same type. Therefore, it is preferable that the reference data is determined for each of the plurality of exposure apparatuses and for each of the illumination conditions and the reference data is stored in the storage unit 45.

When the reference data concerning the reference sample focus curve is stored in the storage unit 45 in Step S407, the diffraction image of the wafer 10 as the inspection object is acquired by image pickup (Step S408). In this procedure, the diffraction images of the wafer 10 are acquired by image pickup respectively under the same diffraction conditions as those of the diffraction images with which the reference sample focus curves selected for the third to fifth image groups G_{C} to G_{E} are obtained. For example, when the one type of reference sample focus curve is selected for the third image group G_{C}, the one type of reference sample focus curve is selected for the fourth image group G_{D}, and the one type of reference sample focus curve is selected for the fifth image group G_{E}, i.e., when the three types of reference sample focus curves in total are selected, then the diffraction images of the wafer 10 are acquired by image pickup under the same three types of the diffraction conditions as those of the diffraction images with which the three types of the reference sample focus curves are obtained.

When the diffraction images of the wafer 10 as the inspection object are acquired by image pickup in Step S408, then the image processing unit 40 judges whether the areas corresponding to the respective pixels are the measuring areas in the shot from the signal intensity of each of the pixels of the diffraction image in relation to each of the groups of the third to fifth image groups G_{C} to G_{E}, and the pixels, which fall under, for example, the street, are excluded from the measuring object. The image processing unit 40 determines the average value of the signal intensities at the measuring point for each of the diffraction images, and the average value is determined as the signal intensity of each of the measuring points (Step S409).

Subsequently, the image processing unit 40 sends the information of the average value of the signal intensities to the inspection unit 42 via the main controller 50. The inspection unit 42 regards the signal intensities determined for the respective groups of the third to fifth image groups G_{C} to G_{E} as the signals of the measuring points indicated by the circles in FIG. 20B to determine the variation state of the focus of the exposure apparatus 101 with respect to the surface of the wafer 10 (hereinafter referred to as “focus state” as well) from the signal intensities (Step S410). In this procedure, the focus offset amount of the exposure apparatus 101 with respect to the surface of the wafer 10 is determined for each of the predetermined pixels (in unit of one pixel or a plurality of pixels) from the signal intensity determined based on the signal intensity of the diffraction image of the wafer 10 by utilizing the reference data stored in the storage unit 45 (i.e., the expression of the approximate curve of the reference sample focus curve or the data map). The positions of the third to fifth pattern areas C to E are different from each other in each of the chips. However, the difference in the position is small as compared with the pitch of the measuring point to determine the focus state. Therefore, it is possible to regard that the signal of the measuring point to determine the focus state is provided.

When the focus offset amounts are determined for all of the measuring points (for the entire surface of the wafer 10) to determine the focus state of the repeating pattern 12 in Step S410, the inspection unit 42 inspects whether or not the determined focus offset amount is abnormal (Step S411). In this procedure, for example, the inspection unit 42 judges that the determined focus offset amount is normal when the determined focus offset amount is within a predetermined threshold value range. The inspection unit 42 judges that the determined focus offset amount is abnormal when the determined focus offset amount is without the predetermined threshold value range.

When the presence or absence of the abnormality of the focus offset amount is inspected in Step S411, then the image processing unit 40 generates the image of the wafer 10 (see FIG. 17) in which the focus offset amounts determined for the respective pixels are converted into the signal intensities of the respective pixels, and the image is displayed on the image display apparatus 46 together with, for example, the inspection result of the focus offset amount (Step S412). The image of the concerning wafer 10 and the inspection result are stored in the storage unit 45.

The process in Step S410, in which the signals of the third to fifth pattern areas C to E of the respective chips are regarded as the signals of the measuring points, is the process in which the signal intensities of the measuring points are determined in accordance with the nearest neighbor interpolation in the second embodiment described above in different words. Also in the third embodiment, it is also allowable to determine the signal intensities of the measuring points from the third to fifth pattern areas C to E by using, for example, the linear interpolation or the cubic convolution interpolation without using the nearest neighbor interpolation. The focus state can be measured while further decreasing the error, by using the interpolation having satisfactory accuracy.

As described above, according to the surface inspection apparatus 1 of the third embodiment, the measuring areas are judged and the signal intensities are measured for the respective groups of the third to fifth image groups G_{C} to G_{E}, wherein the determined signal intensities are regarded as the signals of the measuring point for determining the focus state. The variation state of the focus of the exposure apparatus 101 is determined in relation to all of the measuring points of the repeating pattern 12 (for the entire surface of the wafer 10) from the signal intensities of the third to fifth image groups G_{C} to G_{E} regarded as the signals of the measuring points. Accordingly, even in the case of the wafer 10 for the logic device in which the areal size of the pattern formed on the wafer 10 is small and a large number of areas having differently constructed patterns exist, it is possible to determine the focus state during the exposure based on the image of the wafer 10 subjected to the exposure with the mask pattern to be used for the actual exposure. Therefore, any considerable time is not required for the condition setting operation for the parameter required for the measurement to be performed with the mask for exclusive use, unlike the case in which the mask (reticle) for exclusive use is used. Therefore, it is possible to measure the focus state during the exposure in a short period of time. Further, the pattern to be used for the actual device can be used without using any mask pattern for exclusive use. Furthermore, the illumination condition of the exposure apparatus 101 is not restricted as well. Therefore, it is possible to accurately measure the focus state during the exposure.

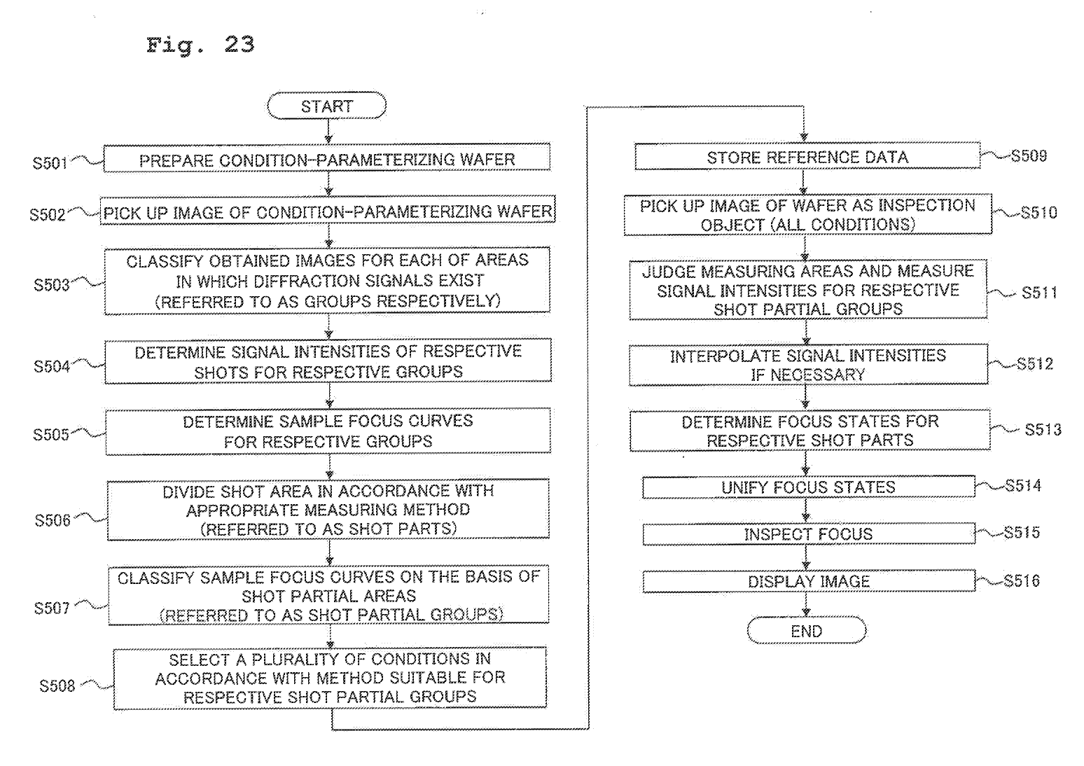

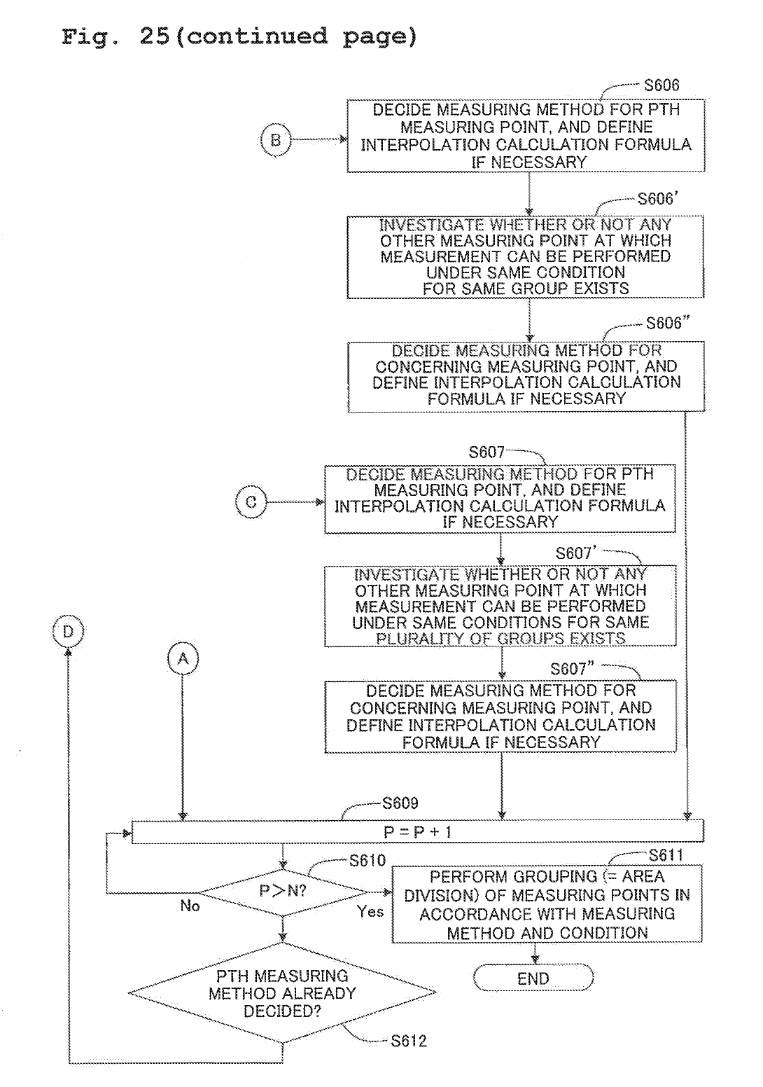

Next, an explanation will be made with reference to FIGS. 22 and 25 about a fourth embodiment of the method for determining the focus state during the exposure performed by the exposure apparatus 101. FIG. 22 shows an arrangement structure different from that of the embodiment described above, of the pattern on the surface of the wafer 10. In the fourth embodiment, a plurality of chip areas 11′ are arranged on the surface of the wafer 10, and the repeating pattern 12′ is formed in the chip area 11′. The repeating pattern 12′ is constructed to include a first pattern area A, a second pattern area B, a third pattern area C, a fourth pattern area D, a fifth pattern area E, and a sixth pattern area F having repeating patterns constructed differently from each other. The wafer 10 is also a wafer for a logic device in which the areal size of the pattern formed on the surface is small and a plurality of areas having differently constructed patterns exist.

It is assumed that the following pattern construction is provided. That is, as for the first and second pattern areas A, B, it is possible to select a plurality of diffraction conditions required for the focus measurement for the areas A and B respectively as described in the first embodiment. However, as for the third to fifth pattern areas C to E, it is impossible to select a plurality of diffraction conditions required for the focus measurement singly respectively as described in the second and third embodiments. It is assumed that the sixth pattern area F has the memory-related pattern construction.

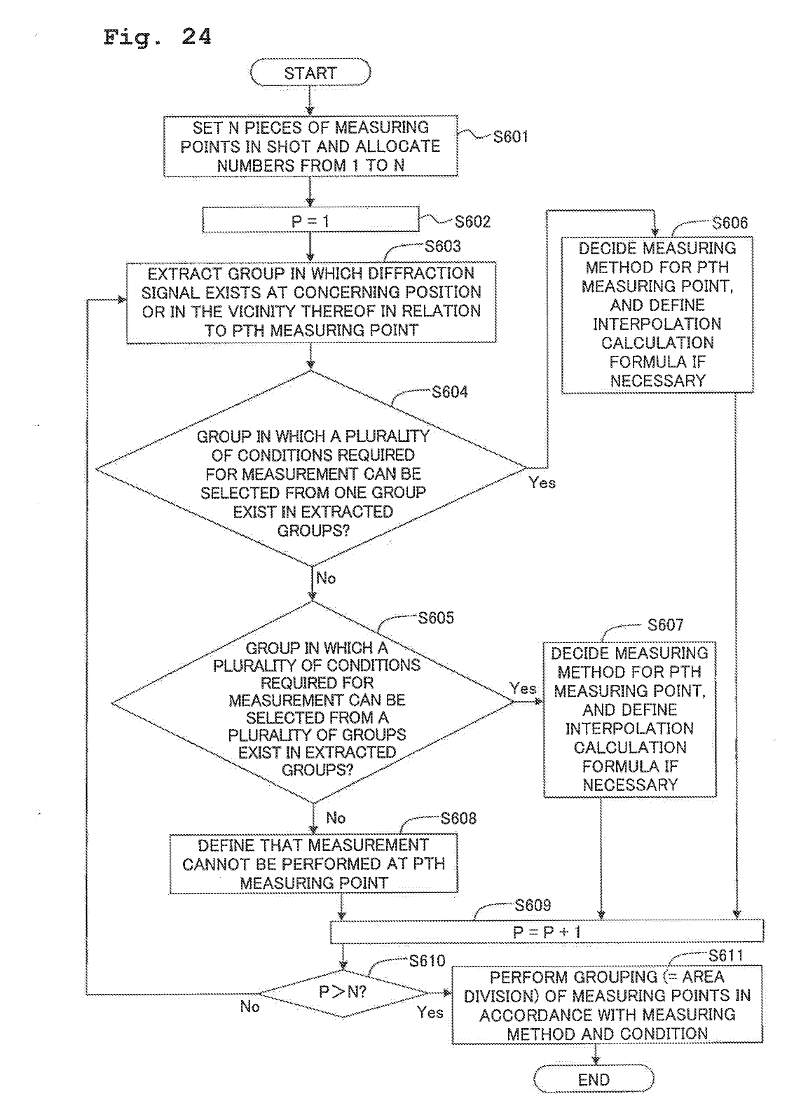

As shown in FIG. 23, Steps S501 to S505 in the fourth embodiment are the same as Steps S201 to S205 of the first embodiment described above as shown in FIG. 13. That is, a condition-varied wafer 10b (see FIG. 14) is prepared (Step S501), and the condition-varied wafer 10b is subjected to the image pickup under various diffraction conditions (Step S502). A plurality of obtained diffraction images are classified into those which capture the diffraction signals of the respective areas of the first to sixth pattern areas A to F (Step S503). The signal intensity is measured for each of the diffraction images in relation to each of the first to sixth image groups G_{A} to G_{F} to determine the shot average value (Step S504) and determine the sample focus curve for each of the groups (Step S505).

Subsequently, the inspection unit 42 divides the shot into shot partial areas subjected to the grouping of the measuring points capable of being measured under the same diffraction condition by using the same measuring method in relation to the measuring points in the shot based on the sample focus curve of each of the groups determined in Step S505 (Step S506).

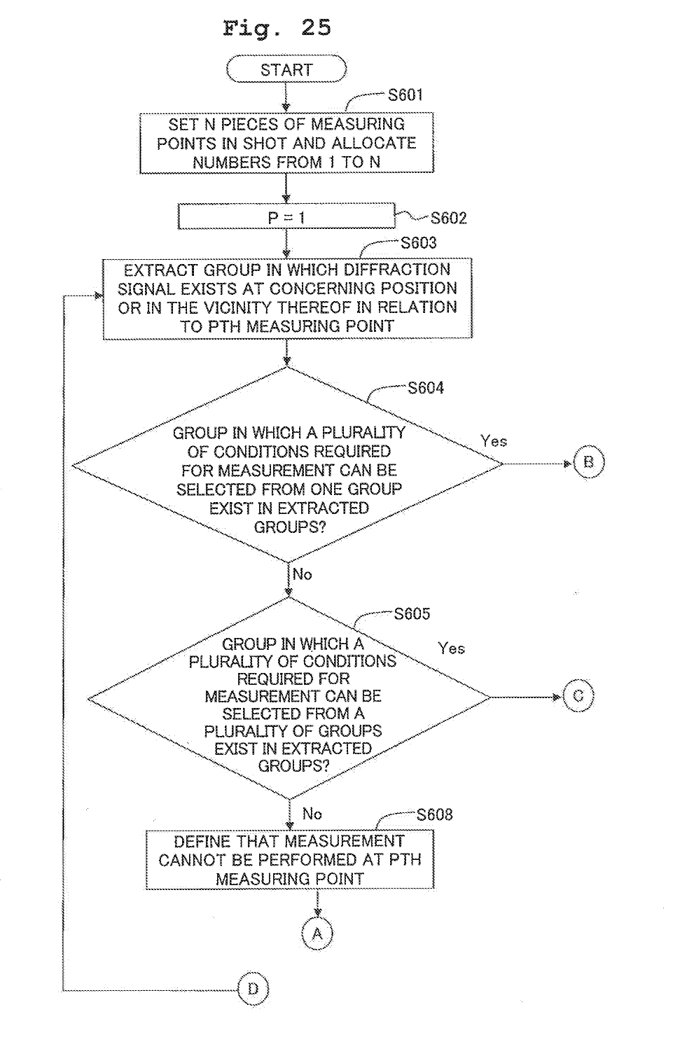

In the dividing method, for example, as shown in FIG. 24, N pieces (N is an integer) of measuring points in the shot are set, and numbers of 1 to N are varied (allotted) thereto (Step S601). The measuring method is investigated and decided for each of the measuring points, provided that the number to be currently investigated is designated as P and P=1 is given (Step S602). As for the Pth measuring point, the pattern area (group), in which the diffraction signal exists at the concerning position or in the vicinity thereof, is extracted (Step S603). The extracted pattern areas are investigated in sequence to investigate whether or not the pattern area, in which a plurality of diffraction conditions required to measure the Pth measuring point can be selected from one pattern area, exists (Step S604). When such a pattern area exists, then the measuring method for the Pth measuring point, i.e., the measurement under a plurality of diffraction conditions selected from one pattern area, and the diffraction condition thereof are decided, and the calculation formula is defined to perform the interpolation from any diffraction signal in the vicinity thereof, when necessary (Step S606). On the other hand, when one pattern area, in which a plurality of diffraction conditions to measure the focus state of the measuring point, does not exist in Step S604, it is investigated whether or not any combination, in which a plurality of diffraction conditions required for the measurement can be selected from a plurality of extracted pattern areas, exists (Step S605). When such a combination exists, the measuring method for the Pth measuring point, i.e., the measurement under a plurality of diffraction conditions selected from a plurality of pattern areas, and the diffraction condition thereof are decided, and the calculation formula is defined to perform the interpolation from any diffraction signal in the vicinity thereof, when necessary (Step S607). On the other hand, when a plurality of diffraction conditions required for the measurement cannot be selected even from a plurality of pattern areas in Step S605, it is defined that the measurement cannot be performed at the measuring point (Step S608). After Steps S606 to S608, the number P for the investigation of the measuring method is subjected to the increment by 1 (Step S609). When P exceeds N, it is approved that the measuring methods have been decided for all of the measuring points including (those in which the measurement cannot be performed) as well (Step S610). Therefore, the measuring points, which involve the same measuring method and the same diffraction condition, are subjected to the grouping (Step S611), and the division of the shot partial area is completed.

When the actual measurement is performed, it is necessary to acquire the images under all of the diffraction conditions required for the measurement of all of the measuring points. Therefore, when the number of the diffraction conditions is increased, the measuring time is consequently increased. For this reason, it is necessary to decrease the number of the diffraction conditions required for the measurement of all of the measuring points as less as possible. Therefore, for example, as shown in FIG. 25, the following procedure is effective. That is, when the measurement method and the diffraction condition for one measuring point are determined, for example, it is investigated whether any other measuring point, which can be measured by the same measuring method and the same diffraction condition, is present or absent (Steps S606′, S606′, S607′, S607′) so that one diffraction condition is commonly used for as a large number of measuring points as possible.

When the shot is divided into a plurality of shot partial areas as described above, as shown in FIG. 22B, the shot is divided into a first shot partial area X which has the first pattern areas A and the second pattern areas B, a second shot partial area Y which has the third pattern areas C, the fourth pattern areas D, and the fifth pattern areas E, and a third shot partial area Z which has the sixth pattern areas F in the case of the condition-varied wafer 10b.

When the shot is divided into the plurality of shot partial areas in Step S506, the plurality of sample focus curves, which are determined in Step S505, are classified into those corresponding to the first to third shot partial areas X to Z respectively (Step S507). The reference sample focus curve, which is used to determine the focus state during the exposure, is selected for each of the shot partial areas (Step S508). In order to select and decide the reference sample focus curve, in the same manner as in the embodiment described above, the sample focus curves, which have the sensitivities to the change of the focus offset amount (have the high focus sensitivities), are firstly extracted from the plurality of sample focus curves. Subsequently, the sample focus curves, which have the weak sensitivities to the change of the dose amount (have the low dose sensitivities) and which suffer less influence exerted by the underlying base change, are extracted from the sample focus curves having the high focus sensitivities. Further, the sample focus curves, in which the positions of the peaks or the bottoms of the curves (focus offset amounts) are different from each other, are selected and decided as the reference sample focus curves from the sample focus curves which have the high focus sensitivities, which have the low dose sensitivities, and which suffer less influence exerted by the underlying base change.

When the reference sample focus curves are selected and decided for the respective shot partial areas in Step S508, then the image processing unit 40 outputs, as the reference data, the data concerning the expressions of the approximate curves of the reference sample focus curves decided for the first to third shot partial areas X to Z respectively to the storage unit 45, and the image processing unit 40 allows the storage unit 45 to store the data (Step S509). The image processing unit 40 can output a data map to indicate the relationship between the focus offset amount determined from the expression of the approximate curve and the signal intensity as the reference data to the storage unit 45, and the image processing unit 40 can allow the storage unit 45 to store the data map, without being limited to the expression of the approximate curve of the reference sample focus curve.

When a plurality of exposure apparatuses 101 exist, the imaging characteristic can differ depending on the apparatus even when the exposure apparatus 101 is of the same type. Therefore, it is preferable that the reference data is determined for each of the plurality of exposure apparatuses and for each of the illumination conditions and the reference data is stored in the storage unit 45.

When the reference data concerning the reference sample focus curve is stored in the storage unit 45 in Step S509, the diffraction image of the wafer 10 as the inspection object is acquired by image pickup (Step S510). In this procedure, the diffraction images of the wafer 10 are acquired by image pickup respectively under the same diffraction conditions as those of the diffraction images with which the reference sample focus curves selected for the first to third shot partial areas X to Z are obtained.

When the diffraction images of the wafer 10 as the inspection object are acquired by image pickup in Step S510, then the image processing unit 40 judges whether the areas corresponding to the respective pixels are the measuring areas in the shot from the signal intensity of each of the pixels of the diffraction image in relation to each of the areas in the first to third shot partial areas X to Z, and the pixels, which fall under, for example, the street, are excluded from the measuring object. The image processing unit 40 determines the average value of the signal intensities at the measuring point for each of the diffraction images, and the average value is determined as the signal intensity of each of the measuring points (Step S511). The signal intensity is determined by means of the interpolation, when necessary (Step S512).

Subsequently, the image processing unit 40 sends the information of the average value of the signal intensities to the inspection unit 42 via the main controller 50. The inspection unit 42 determines the variation state of the focus of the exposure apparatus 101 with respect to the surface of the wafer 10 (focus state) from the diffraction image of the wafer 10 as the inspection object for each of the areas in the first to third shot partial areas X to Z (Step S513). In this procedure, the focus offset amount of the exposure apparatus 101 with respect to the surface of the wafer 10 is determined for each of the measuring points from the signal intensity determined based on the signal intensity of the diffraction image of the wafer 10 by utilizing the reference data stored in the storage unit 45 (i.e., the expression of the approximate curve of the reference sample focus curve or the data map).

When the variation states of the focus of the exposure apparatus 101 are determined for the respective areas of the first to third shot partial areas X to Z in Step S513, the variation states are unified to determine the variation states of the focus of the exposure apparatus 101 at all of the measuring points of the repeating pattern 12′ (Step S514).

When the focus offset amounts are determined for all of the measuring points (for the entire surface of the wafer 10) to determine the focus state of the repeating pattern 12 in Step S514, the inspection unit 42 inspects whether or not the determined focus offset amount is abnormal (Step S515). In this procedure, for example, the inspection unit 42 judges that the determined focus offset amount is normal when the determined focus offset amount is within a predetermined threshold value range. The inspection unit 42 judges that the determined focus offset amount is abnormal when the determined focus offset amount is without the predetermined threshold value range.

When the presence or absence of the abnormality of the focus offset amount is inspected in Step S515, then the image processing unit 40 generates the image of the wafer 10 (see FIG. 17) in which the focus offset amounts determined for the respective pixels are converted into the signal intensities of the respective pixels, and the image is displayed on the image display apparatus 46 together with, for example, the inspection result of the focus offset amount (Step S516). The image of the concerning wafer 10 and the inspection result are stored in the storage unit 45.

When the shot is divided into the plurality of shot partial areas in Step S506, when there is any shot partial area in which the focus measurement cannot be performed on account of the pattern condition, then the concerning part is regarded as the shot measurement disabled partial area, and the measurement is not performed therefor.

As described above, according to the surface inspection apparatus of the fourth embodiment, the shot is divided into the shot partial areas in which the measuring points capable of being measured by the same measuring method and under the same diffraction condition are subjected to the grouping, based on the sample focus curves determined for the respective pattern areas of the first to sixth image groups G_{A} to G_{F}. Further, the focus variation states of the exposure apparatus 101, which are determined for the respective shot partial areas, are unified to determine the focus variation state of the exposure apparatus 101 in relation to all of the measuring points (for the entire surface of the wafer 10) of the repeating pattern 12′. Accordingly, even in the case of the wafer 10 for the logic device in which the areal size of the pattern formed on the wafer 10 is small and a large number of areas having differently constructed patterns exist, it is possible to determine the focus state during the exposure based on the image of the wafer 10 subjected to the exposure with the mask pattern to be used for the actual exposure. Therefore, any considerable time is not required for the condition setting operation for the parameter required for the measurement to be performed with the mask for exclusive use, unlike the case in which the mask (reticle) for exclusive use is used. Therefore, it is possible to measure the focus state during the exposure in a short period of time. Further, the pattern to be used for the actual device can be used without using any mask pattern for exclusive use. Furthermore, the illumination condition of the exposure apparatus 101 is not restricted as well. Therefore, it is possible to accurately measure the focus state during the exposure.

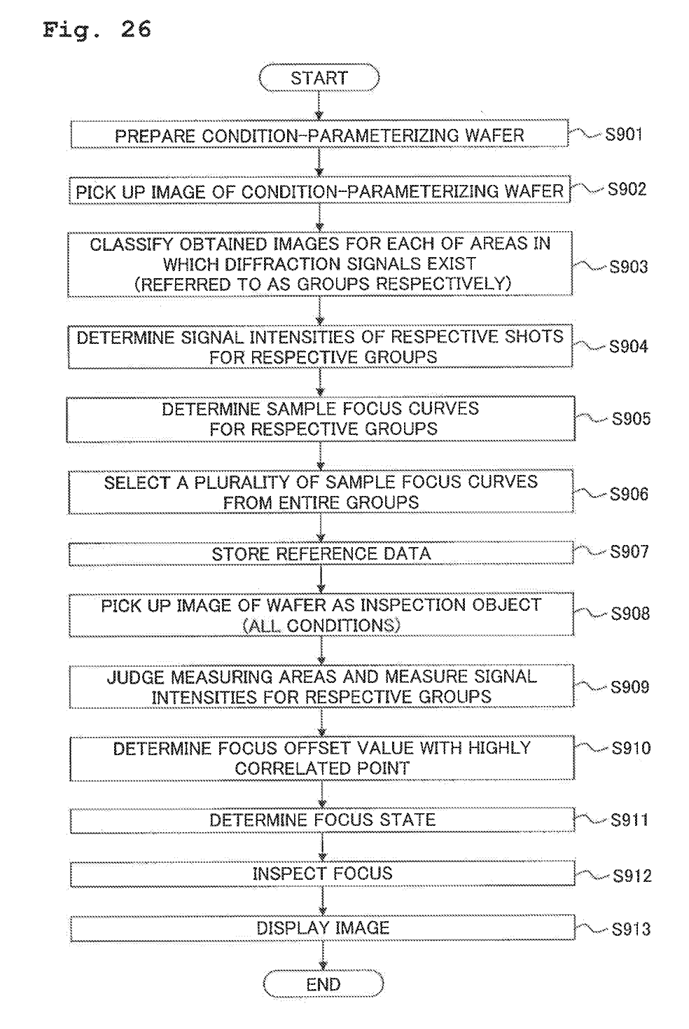

Next, an explanation will be made with reference to a flow chart shown in FIG. 26 about a fifth embodiment of the method for determining the focus state during the exposure performed by the exposure apparatus 101. In the fifth embodiment, an explanation will be made about a method for determining the focus state during the exposure when a plurality of diffraction conditions, which are required for the measurement of the focus state, cannot be determined for the first and second pattern areas A, B respectively. It is assumed that the arrangement structure of the repeating pattern is the same as or equivalent to that shown in FIG. 4 used to explain the first embodiment, and reference is made to the same FIG. 4.

As shown in FIG. 26, Steps S901 to S905 in the fifth embodiment are the same as Steps S201 to S205 of the first embodiment described above as shown in FIG. 13. That is, a condition-varied wafer 10b (see FIG. 14) is prepared (Step S901), and the condition-varied wafer 10b is subjected to the image pickup under various diffraction conditions (Step S902). A plurality of obtained diffraction images are classified into those which capture the diffraction signal of the first pattern area A and those which capture the diffraction signal of the second pattern area B (Step S903). The signal intensity is measured for each of the diffraction images in relation to each of the first image group G_{A} and the second image group G_{B} to determine the shot average value (Step S904) and determine the sample focus curve (Step S905).

Subsequently, the inspection unit 42 selects at least one set (at least one type from the first image group G_{A} and one type from the second image group G_{B}) of the reference sample focus curves to be used in order to determine the focus state during the exposure from the plurality of sample focus curves in relation to the first image group G_{A} and the second image group G_{B} (Step S906). For example, one type in the first image group G_{A} and two types in the second image group G_{B}, i.e., three types in total of the reference sample focus curves are selected and decided. In order to select and decide the reference sample focus curves, in the same manner as in the embodiment described above, the sample focus curves, which have the sensitivities to the change of the focus offset amount (have the high focus sensitivities), are firstly extracted from the plurality of sample focus curves. Subsequently, the sample focus curves, which have the weak sensitivities to the change of the dose amount (have the low dose sensitivities) and which suffer less influence exerted by the underlying base change, are extracted from the sample focus curves having the high focus sensitivities. Further, the sample focus curves, in which the positions of the peaks or the bottoms of the curves (focus offset amounts) are different from each other, are selected and decided as the reference sample focus curves from the sample focus curves which have the high focus sensitivities, which have the low dose sensitivities, and which suffer less influence exerted by the underlying base change.

When the reference sample focus curves are selected and decided in Step S906, then the image processing unit 40 outputs, as the reference data, the data concerning the expressions of the approximate curves of the reference sample focus curves decided for the first image group G_{A} and the second image group G_{B} respectively to the storage unit 45, and the image processing unit 40 allows the storage unit 45 to store the data (Step S907). The image processing unit 40 can output a data map to indicate the relationship between the focus offset amount determined from the expression of the approximate curve and the signal intensity as the reference data to the storage unit 45, and the image processing unit 40 can allow the storage unit 45 to store the data map, without being limited to the expression of the approximate curve of the reference sample focus curve.

When a plurality of exposure apparatuses 101 exist, the imaging characteristic can differ depending on the apparatus even when the exposure apparatus 101 is of the same type. Therefore, it is preferable that the reference data is determined for each of the plurality of exposure apparatuses and for each of the illumination conditions and the reference data is stored in the storage unit 45.

When the reference data concerning the reference sample focus curve is stored in the storage unit 45 in Step S907, the diffraction image of the wafer 10 as the inspection object is acquired by image pickup (Step S908). In this procedure, the diffraction images of the wafer 10 are acquired by image pickup respectively under the same diffraction conditions as those of the diffraction images with which the reference sample focus curves selected for the first image group G_{A} are obtained. Further, the diffraction images of the wafer 10 are acquired by image pickup respectively under the same diffraction conditions as those of the diffraction images with which the reference sample focus curves selected for the second image group G_{B} are obtained. For example, when the one type of reference sample focus curve is selected for the first image group G_{A}, and the two types of reference sample focus curves are selected for the second image groups G_{B}, i.e., when the three types of reference sample focus curves in total are selected, then the diffraction images of the wafer 10 are acquired by image pickup under the same three types of the diffraction conditions as those of the diffraction images with which the three types of the reference sample focus curves are obtained.

When the diffraction images of the wafer 10 as the inspection object are acquired by image pickup in Step S908, then the image processing unit 40 judges whether the areas corresponding to the respective pixels are the measuring areas in the shot from the signal intensity of each of the pixels of the diffraction image in relation to each of the groups of the first and second image groups G_{A}, G_{B}, and the pixels, which fall under, for example, the street, are excluded from the measuring object. The image processing unit 40 determines the average value of the signal intensities at the measuring point for each of the diffraction images, and the average value is determined as the signal intensity of each of the measuring points (Step S909).

In this procedure, for example, only one type of the reference sample focus curve is selected for the first image group G_{A}, and hence the image processing unit 40 cannot decide the focus offset amount unambiguously. For example, when it is assumed with reference to FIG. 16 that the measured value at a certain measuring point is K1 and the reference sample focus curve D1 is selected, then about 0.05 and about −0.14 are given as candidates of the focus offset amounts. When this goes on, it is impossible to unambiguously decide the focus offset.

In view of the above, the image processing unit 40 determines the portion (highly correlated point) which is highly correlated with the measuring point without being affected by the dose variation and the underlying base, and the focus offset is decided by using the measuring point and the highly correlated point (Step S910). In this procedure, in the case of the scanning exposure, the highly correlated point is determined from those disposed in a range of ⅛ of the shot in the slit longitudinal direction and 1/16 of the shot in the scanning direction. In the case of the full field exposure, the highly correlated point is determined from those disposed in a range of ⅛ for both of X and Y. The following procedure is given as an example of the method for determining the highly correlated point. A reference sample focus curve (for example, one type), which is provided at a certain point within the range as described above, is added to the reference sample focus curves (for example, two types) at the measuring point, and thus it is assumed that three types of the reference sample focus curves are prepared. The focus offset amount, in which the sum of squares of differences with respect to the signal intensities is minimized, is determined by using the three type of the reference sample focus curves in the same manner as in the first embodiment. In this procedure, several points are subjected to the search within the range described above, and thus the search is performed for the point at which the minimum value of the sum of squares of differences is minimized or most decreased. In this way, the search is performed within the range described above for the point at which the minimum value of the sum of squares of differences determined in the procedure described above is minimized or most decreased, and thus it is possible to determine the highly correlated point.

In this way, the image processing unit 40 determines, for each of the measuring points, the focus offset amount of the exposure apparatus 101 with respect to the surface of the wafer 10 by utilizing not only the reference sample focus curve at the measuring point but also the reference sample focus curve at the highly correlated point highly correlated with the measuring point (Step S911). When the measuring point does not reside in a plurality of pixels, but the measuring point resides in one pixel, the focus offset is determined for each of the pixels.

When the focus offset amounts of all of the measuring points of the repeating pattern 12 are determined in Step S911, the inspection unit 42 inspects whether or not the determined focus offset amount is abnormal (Step S912). In this procedure, for example, the inspection unit 42 judges that the determined focus offset amount is normal when the determined focus offset amount is within a predetermined threshold value range. The inspection unit 42 judges that the determined focus offset amount is abnormal when the determined focus offset amount is without the predetermined threshold value range.

When the presence or absence of the abnormality of the focus offset amount is inspected in Step S912, then the image processing unit 40 generates the image of the wafer 10 (see FIG. 17) in which the focus offset amounts determined for the respective measuring points are converted into the signal intensities at the respective measuring points, and the image is displayed on the image display apparatus 46 together with, for example, the inspection result of the focus offset amount (Step S913). The image of the concerning wafer 10 and the determined focus offset amounts and the inspection result are stored in the storage unit 45.

As described above, according to the surface inspection apparatus 1 of the fifth embodiment, the measuring areas are judged and the signal intensities are measured for the respective groups of the first and second image groups G_{A}, G_{B}. In this procedure, when the three types of the reference sample focus curves are not prepared at the measuring point, the three types of the reference sample focus curves are prepared by adding the reference sample focus curve at the highly correlated point highly correlated with the measuring point as well. Accordingly, even in the case of the wafer 10 for the logic device in which the areal size of the pattern formed on the wafer 10 is small and a large number of areas having differently constructed patterns exist, it is possible to determine the focus state during the exposure based on the image of the wafer 10 exposed with the mask pattern to be used for the actual exposure. Therefore, any considerable time is not required for the condition setting operation for the parameter required for the measurement to be performed with the mask for exclusive use, i.e., the operation such as the test exposure and the line width measurement, unlike the case in which the mask (reticle) for exclusive use is used. Therefore, it is possible to measure the focus state during the exposure in a short period of time. The pattern to be used for the actual device can be used without using any mask pattern for exclusive use. Further, the illumination condition of the exposure apparatus 101 is not restricted as well. Therefore, it is possible to accurately measure the focus state during the exposure.

In the embodiment described above, the three types of reference data (reference sample focus curves D1 to D3) are used to measure the focus state during the exposure (processing condition) with respect to the repeating pattern 12 on the wafer 10. However, there is no limitation thereto. For example, it is also allowable to use two types of reference data or five types of reference data. It is appropriate to measure the focus state during the exposure by using at least two types of reference data in which the way of change of the detection signal with respect to the focus change is different.

In the embodiment described above, the inspection is performed for the repeating pattern 12 formed by the exposure on the resist film on the wafer 10. However, there is no limitation thereto. It is also allowable that a pattern after the etching is inspected. Accordingly, it is possible to detect not only the focus state during the exposure but also any inconvenience (abnormality) during the etching.

In the embodiment described above, the following procedure is also available. That is, a plurality of sample focus curves, which are based on the polarization as decided, for example, by the wafer orientation angle and the illumination wavelength, are determined for each of different dose amounts in accordance with the same or equivalent method as that described above by utilizing the polarized image (PER image) of the condition-varied wafer 10b in addition to the diffraction image of the condition-varied wafer 10b. A plurality of reference sample focus curves based on the polarization are selected and decided therefrom. Accordingly, when the variation state of the focus of the exposure apparatus 101 with respect to the surface of the wafer 10 is determined from the signal intensity of the polarized image acquired by image pickup by the image pickup device 35 by using the reference sample focus curve (reference data) based on the polarization, the number of detection conditions is increased as compared with the case in which only the diffraction image is used. Therefore, it is possible to measure the focus state during the exposure more accurately. In relation to the polarization, it is considered that the focus offset amount, at which the signal intensity is locally maximized on the focus curve, provides the best focus. Therefore, it is possible to easily know the focus offset amount at which the best focus is provided. The diffraction image and the polarized image can be used in combination, for example, such that the first detection signal resides in the diffraction image and the second detection signal resides in the polarized image.

In the embodiment described above, the three types of reference data (reference sample focus curves D1 to D3), in which the sensitivity is given for the change of the focus and the weak sensitivity is given for the change of the dose amount, are used to measure the focus state during the exposure with respect to the repeating pattern 12 on the wafer 10. However, a plurality of sample focus curves, in which the sensitivity is given to the change of the dose amount and the weak sensitivity is given to the change of the focus, can be extracted from the plurality of sample focus curves. Accordingly, the dose amount during the exposure with respect to the repeating pattern 12 on the wafer 10 can be also measured by utilizing sample dose curves obtained similarly by replacing the focuses of the sample focus curves with the doses. As for the change of the dose amount, the signal intensity of the diffraction or polarization undergoes the monotonic decrease or the monotonic increase in accordance with the increase in the dose amount. In such a situation, one type of sample focus curve can be used for the measurement without using a plurality of sample focus curves, for the following reason. That is, when the sample dose curve monotonically decreases or monotonically increases, it is possible to unambiguously decide the dose amount from the signal intensity during the measurement.

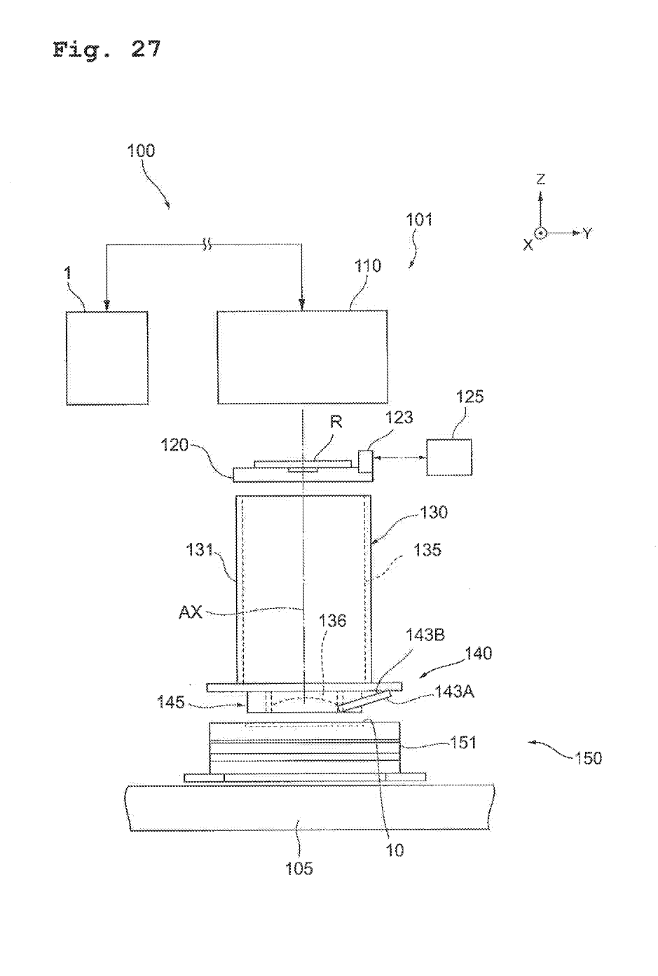

In the embodiment described above, the variation state of the focus of the exposure apparatus 101 with respect to the surface of the wafer 10 determined by the inspection unit 42 (focus offset amount) can be outputted from the main controller 50 via the signal output unit 60 to the exposure apparatus 101 to provide the feedback to the setting of the exposure apparatus 101. Accordingly, an exposure system, which is provided with the surface inspection apparatus 1 described above, will be explained with reference to FIG. 27. The exposure system 100 is constructed to include the exposure apparatus 101 which projects a predetermined mask pattern (repeating pattern) onto the surface of the wafer 10 coated with the resist to perform the exposure, and the surface inspection apparatus 1 which performs the inspection of the wafer 10 having the repeating pattern 12 formed on the surface after executing, for example, an exposure step performed by the exposure apparatus 101 and a development step performed by the developing apparatus (not shown).

As shown in FIG. 27, the exposure apparatus 101 is constructed to include an illumination system 110, a reticle stage 120, a projection unit 130, a local liquid immersion apparatus 140, a stage apparatus 150, and a main controller (not shown). The following explanation will be made assuming that the directions of the arrows X, Y, Z shown in FIG. 27 are designated as the X axis direction, the Y axis direction, and the Z axis direction respectively.

Although any detailed illustration is omitted from the drawing, the illumination system 110 includes a light source, an ilbrightness uniformalizing optical system provided with, for example, an optical integrator, and an illumination optical system provided with, for example, a reticle blind. The illumination system 110 is constructed so that a slit-shaped illumination area on the reticle R, which is defined by the reticle blind, is illuminated with the illumination light (exposure light) at a substantially uniform ilbrightness. For example, an ArF excimer laser beam (wavelength: 193 nm) is used as the illumination light.

The reticle (photomask) R, which has a predetermined pattern (for example, a line pattern) formed on the pattern surface thereof (lower surface as viewed in FIG. 27), is fixed and retained, for example, by means of the vacuum attraction on the reticle stage 120. The reticle stage 120 is constructed to be movable in the XY plane by a reticle stage driving apparatus provided with, for example, a linear motor and movable at a predetermined scanning velocity in the scanning direction (assumed to be the Y axis direction in this case).

The position information in the XY plane of the reticle stage 120 (including the information of the rotation in the rotating direction about the Z axis) is detected by a reticle interferometer 125 by the aid of a first reflecting mirror 123 having a reflecting surface perpendicular to the Y axis and a second reflecting mirror (not shown) having a reflecting surface perpendicular to the X axis provided for the reticle stage 120. The position information, which is detected by the reticle interferometer 125, is sent to the main controller. The main controller controls the position (and the movement velocity) of the reticle stage 120 by the aid of the reticle stage driving apparatus based on the position information.

The projection unit 130 is arranged under or below the reticle stage 120, and the projection unit 130 is constructed to include a barrel 131 and a projection optical system 135 retained in the barrel 131. The projection optical system 135 has a plurality of optical elements (lens elements) arranged along the optical axis AX of the illumination light. The projection optical system 135 is constructed to be telecentric on the both sides and have a predetermined projection magnification (for example, ¼ fold, ⅕ fold, or ⅛ fold). Therefore, when the illumination area on the reticle R is illuminated with the illumination light allowed to outgo from the illumination system 110, a reduction image of the pattern of the reticle R in the illumination area is formed in the exposure area (area conjugate with the illumination area on the reticle R) on the wafer 10 arranged on the image plane side of the projection optical system 135 via the projection optical system 135 by the illumination light transmitted through the reticle R arranged such that the object plane of the projection optical system 135 and the pattern plane are substantially coincident with each other. Further, the reticle R is moved in the scanning direction (Y axis direction) with respect to the illumination area, and the wafer 10 is moved in the scanning direction (Y axis direction) with respect to the exposure area by synchronously driving the reticle stage 120 and the stage apparatus 150 which retains the wafer 10. Thus, the scanning exposure is performed for one shot area on the wafer 10, and the pattern of the reticle R (mask pattern) is transferred to the shot area.

The stage apparatus 150 is constructed to include a wafer stage 151 which is arranged under or below the projection unit 130 and a stage driving apparatus (not shown) which drives the wafer stage 151. The wafer stage 151 is constructed so that the wafer 10 is retained by means of the vacuum attraction on the upper surface. Further, the wafer stage 151 is movable in the XY plane along the upper surface of a base member 105 by means of a motor for constructing the stage driving apparatus.

The position information in the XY plane of the wafer stage 151 is detected by an encoder device (not shown). The position information detected by the encoder device is sent to the main controller. The main controller controls the position (and the movement velocity) of the wafer stage 151 by the aid of the stage driving apparatus based on the position information.

In the exposure apparatus 101 constructed as described above, when the illumination area on the reticle R is illuminated with the illumination light allowed to outgo from the illumination system 110, the reduction image of the pattern of the reticle R in the illumination area is formed in the exposure area (area conjugate with the illumination area on the reticle R) on the wafer 10 supported on the wafer stage 151 and arranged on the image plane side of the projection optical system 135 via the projection optical system 135 by the illumination light transmitted through the reticle R arranged such that the object plane of the projection optical system 135 and the pattern plane are substantially coincident with each other. Further, the reticle R is moved in the scanning direction (Y axis direction) with respect to the illumination area, and the wafer 10 is moved in the scanning direction (Y axis direction) with respect to the exposure area by synchronously driving the reticle stage 120 and the wafer stage 151 which supports the wafer 10. Thus, the scanning exposure is performed for one shot area on the wafer 10, and the pattern of the reticle R is transferred to the shot area.

When the exposure step is carried out by the exposure apparatus 101 as described above, the surface inspection is performed for the wafer 10 having the surface formed with the repeating pattern 12 by means of the surface inspection apparatus 1 according to the embodiment described above, after performing, for example, the development step performed by the developing apparatus (not shown). Also in this procedure, the inspection unit 42 of the surface inspection apparatus 1 determines the variation state of the focus of the exposure apparatus 101 with respect to the surface of the wafer 10 as described above. The information, which relates to the determined variation state of the focus (focus offset amount), is outputted to the exposure apparatus 101 from the main controller 50, for example, via the signal output unit 60 and a connection cable (not shown). A correction processing unit 210, which is provided for the main controller 200 of the exposure apparatus 101, corrects the arrangement state of the optical element and various setting parameters in relation to the focus of the exposure apparatus 101 so that the focus state of the exposure apparatus 101 with respect to the surface of the wafer 10 is constant (the resist surface is coincident with the image plane of the pattern subjected to the exposure performed by the exposure apparatus, with the dose amount to provide the preset energy amount) based on the variation state of the focus of the exposure apparatus 101 inputted from the surface inspection apparatus 1.

Thus, according to the exposure system 100 of the embodiment of the present teaching, the setting of the focus of the exposure apparatus 101 is corrected depending on the focus state during the exposure inputted from the surface inspection apparatus 1 according to the embodiment described above. Therefore, it is possible to measure the focus state during the exposure accurately in a short period of time. Therefore, the correction can be performed based on the more accurate focus state, and it is possible to perform the setting of the focus of the exposure apparatus 101 more appropriately.

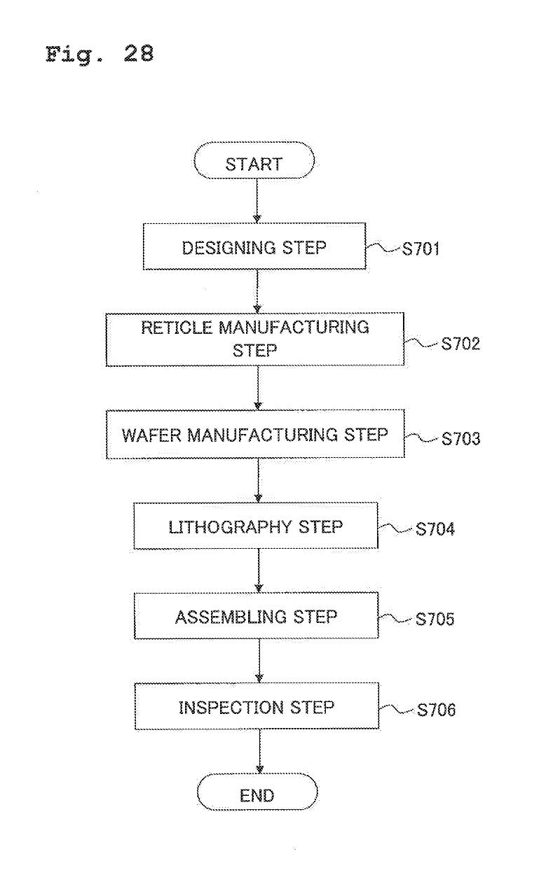

Next, an explanation will be made with reference to FIG. 28 about a method for producing a semiconductor device based on the use of the exposure system 100 as described above. The semiconductor device (not shown) is produced by performing, for example, a designing step of designing the function and the performance of the device (Step S701), a reticle manufacturing step of manufacturing a reticle based on the designing step (Step S702), a wafer manufacturing step of manufacturing a wafer from a silicon material (Step S703), a lithography step of transferring a pattern of the reticle to the wafer by means of, for example, the exposure (including, for example, an exposure step and a development step) (Step S704), an assembling step of assembling the device (including, for example, a dicing step, a bonding step, and a packaging step) (Step S705), and an inspection step for inspecting the device (Step S706).

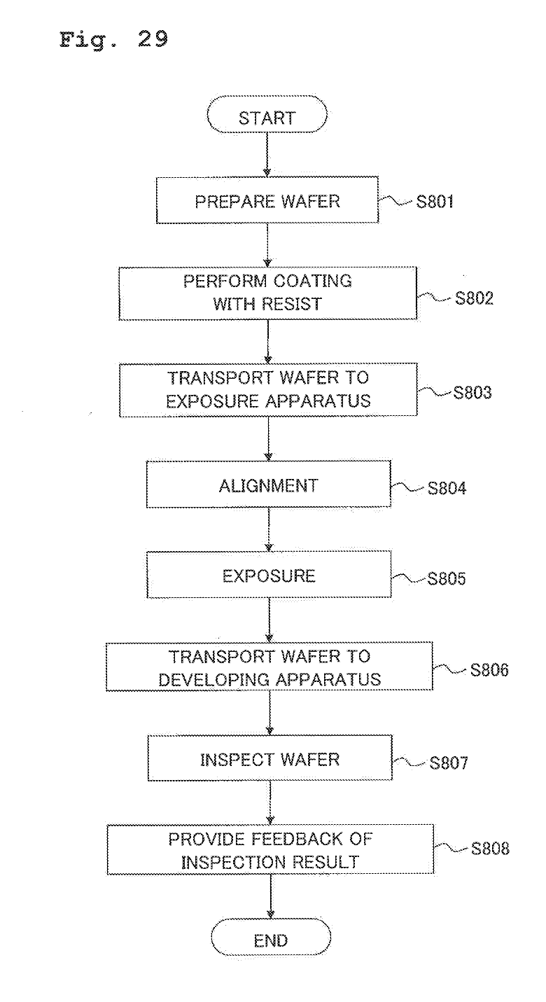

An explanation will now be made with reference to FIG. 29 about details of the lithography step. At first, a wafer is prepared (Step S801), and the surface of the wafer is coated with a resist so that a predetermined thickness is obtained by using a coating apparatus such as an unillustrated spin coater or the like (Step S802). In this procedure, the solvent component of the resist is evaporated by using a drying apparatus included in the coating apparatus, for the wafer for which the coating is completed, and the resist is solidified. The wafer, which has been coated with the resist that has been solidified, is transported to the exposure apparatus 101 by means of an unillustrated transport apparatus (Step S803). The wafer, which is imported into the exposure apparatus 101, is subjected to the alignment by an alignment apparatus provided for the exposure apparatus 101 (Step S804). The wafer, for which the alignment is completed, is subjected to the reduction exposure with a pattern of a reticle (Step S805). The wafer, for which the exposure is completed, is transported from the exposure apparatus 101 to an unillustrated developing apparatus to perform the development (Step S806). The wafer, for which the development is completed, is set to the surface inspection apparatus 1 so that the focus state of the exposure apparatus 101 is determined as described above and the diffraction inspection and the polarization inspection are performed to inspect the pattern manufactured on the wafer (Step S807). Any wafer, on which the defect (abnormality) arises at a level of not less than a preset reference or standard in the inspection, is sent to the rework process (reproduction processing). The wafer, on which the defect (abnormality) is less than the reference or standard, is subjected to the aftertreatment such as the etching process or the like. The focus state of the exposure apparatus 101 determined in Step S807 is subjected to the feedback to the exposure apparatus 101 in order to correct the setting of the focus (Step S808). The exposure is performed for the next substrate by using the exposure apparatus in which the focus state subjected to the feedback becomes constant.

In the method for producing the semiconductor device of this embodiment, the exposure is performed for the pattern by using the exposure system 100 according to the embodiment described above in the lithography step. That is, as described above, when the exposure step is carried out by the exposure apparatus 101, the surface inspection is performed for the wafer 10 having the repeating pattern 12 formed on the surface by using the surface inspection apparatus 1 after performing, for example, the development step performed by the developing apparatus (not shown). In this procedure, the focus state during the exposure is measured by the surface inspection apparatus 1, and the setting of the focus of the exposure apparatus 101 is corrected in accordance with the focus state during the exposure inputted from the surface inspection apparatus 1 in the exposure apparatus 101. In this way, according to the method for producing the semiconductor device of this embodiment, the focus state during the exposure can be accurately measured in a short period of time. Therefore, the setting of the focus of the exposure apparatus 101 can be performed more appropriately, and it is possible to produce the semiconductor device having a high degree of integration while providing superior productivity.

Up to this point, the construction has been explained, in which the focus state on the entire surface of the wafer 10 is measured by using the optical system for collectively or integrally picking up the image of the entire surface of the wafer 10. However, there is no limitation thereto. It is also possible to measure the focus state for each of more detailed areas. For example, when the construction is made such that the image pickup magnification is raised to incorporate one shot as one sheet of image, it is possible to measure the change of the focus state for each of finer areas in units of shots. In this case, the construction of the apparatus is basically the same as the construction of the embodiment described above (surface inspection apparatus 1). However, it is appropriate to add a mechanism such as an XY stage or the like in order to change the relative positions of the wafer and the optical system so that the image pickup magnification of the optical system is raised and the image of each shot in the wafer surface can be picked up.

When the change of the focus state is measured for each of finer areas in units of shots in the apparatus as described above, it is necessary to pick up the images repeatedly in an amount corresponding to the number of shots as measurement objects. Therefore, a considerable time is required for the measurement, but the measurement can be performed in more detail. For example, it is assumed that the pixel size on the wafer is 300 μm when the image of the entire surface of the wafer is collectively or integrally picked up. On this assumption, the pixel size can be made about 30 μm in units of shots. Therefore, the focus state can be measured for each of smaller areas, and a pattern, in which the area of the repeating pattern is small, can be also measured corresponding thereto. Of course, in the case of a wafer on which various patterns are scattered as in the logic wafer, it is necessary to similarly perform, for example, the interpolation of the signal as described above.

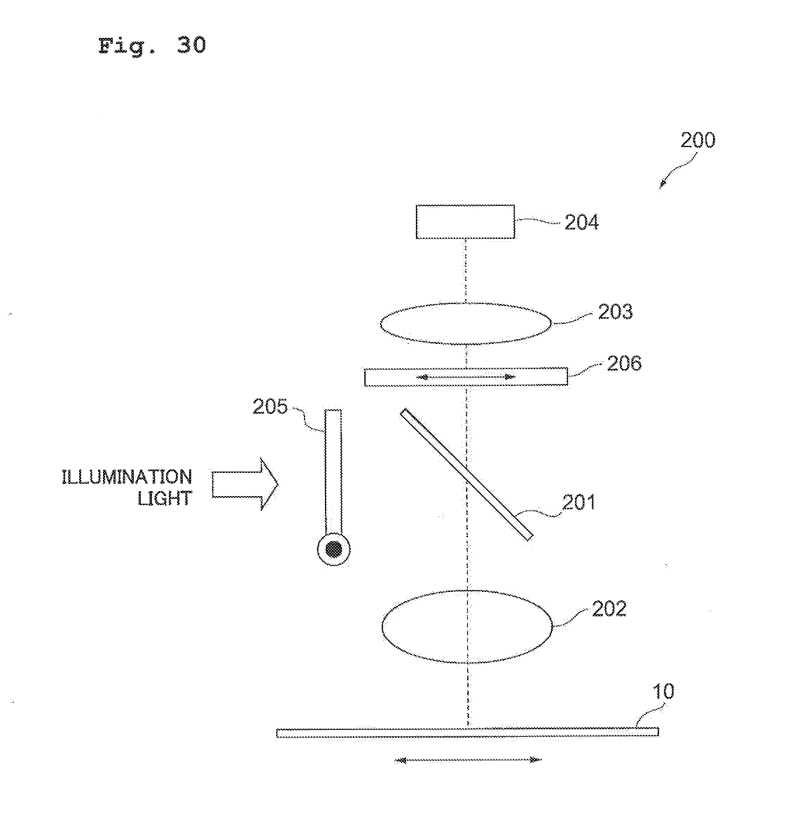

The measurement of the focus state for each of detailed areas as described above can be also performed by using a microscope apparatus. FIG. 30 shows a schematic arrangement of the microscope apparatus 200 provided with an optical system which is constructed by adding a polarizer 205 and an analyzer 206 to a microscope optical system having a half mirror 201, a first objective lens 202, a second objective lens 203, and an image sensor 204 so that the pattern on the wafer 10 is illuminated with the illumination light of linear polarization to detect the change of the polarization state caused by the structural double refraction on the pattern. The microscope apparatus 200 makes it possible to two-dimensionally detect the change of the polarization state on the pattern in the microscope field. Further, when the image pickup is repeated while changing the relative positional relationship between the optical system and the wafer 10, the change of the polarization state on the pattern can be detected densely or sparsely on the entire surface of the wafer 10. In the microscope apparatus 200, it is possible to measure the focus state by acquiring images under a plurality of optical conditions in which the optical conditions including, for example, the wafer orientation angle, the illumination wavelength, the polarizer angle, and the analyzer angle are changed so that a plurality of focus curves are acquired in the same manner as in the embodiment described above. Further, it is possible to measure the focus state of the pattern on the logic wafer by performing, for example, the interpolation of the signal in the same manner as in the embodiment described above.

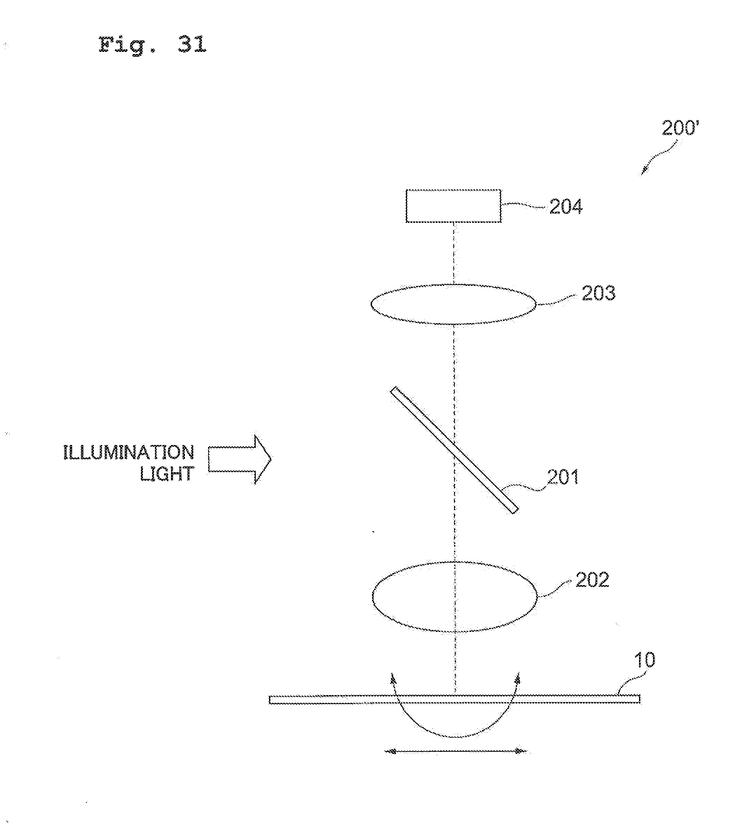

FIG. 31 shows a schematic arrangement of a microscope apparatus 200′ which is constructed by withdrawing the polarizer 205 and the analyzer 206 from the optical path and adding a wafer tilt mechanism capable of tilting (inclining) the surface of the wafer 10 with respect to the optical axis of the illumination light as compared with the microscope apparatus 200 and which is capable of detecting the diffracted light allowed to come from the pattern on the wafer 10. In the microscope apparatus 200′, it is possible to measure the focus state by acquiring images under a plurality of diffraction conditions in which the diffraction conditions including, for example, the wafer orientation angle, the illumination wavelength, the illumination angle (angle of incidence), the outgoing angle, and the order of diffraction are changed by tilting the wafer 10 by means of the wafer tilt mechanism so that a plurality of focus curves are acquired in the same manner as in the embodiment described above. Further, it is possible to measure the focus state of the pattern on the logic wafer by performing, for example, the interpolation of the signal in the same manner as in the embodiment described above. Furthermore, although not shown, the construction can be made such that the optical system for detecting the change of the polarization state shown in FIG. 30 and the diffraction optical system for detecting the diffracted light shown in FIG. 31 are combined to measure the focus state by using the both optical conditions.

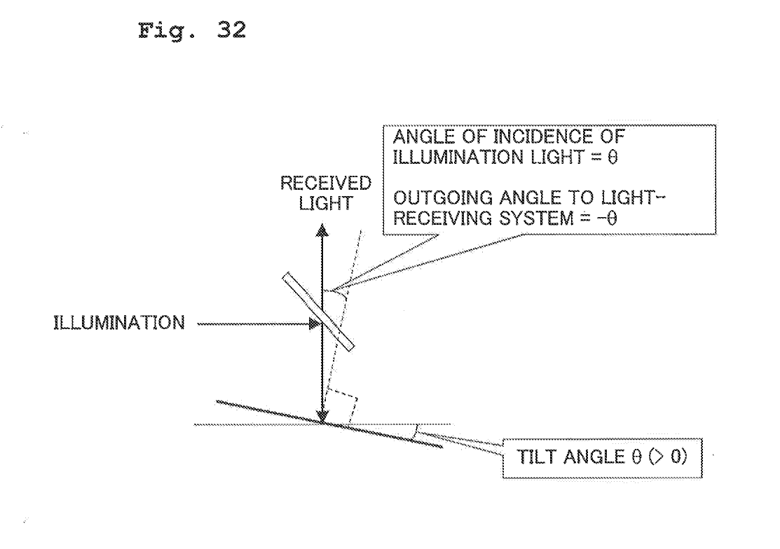

An explanation will now be made about the relationship between the tilt angle of the wafer and the diffracted light by using FIG. 32. A relationship of P(sin θ−sin(−θ))=m) is given between the tilt angle θ of the wafer 10 and the pattern pitch P for generating the diffracted light. This expression is converted into 2P sin θ=mλ. In this expression, m represents the order of diffraction and X represents the wavelength of the illumination light, wherein the clockwise direction is positive for the tilt angle θ. According to this expression, it is possible to detect the diffracted light corresponding to the tilt angle and the pattern pitch. Therefore, in the case of the microscope apparatus 200′, it is possible to acquire images under a plurality of diffraction conditions by tilting the wafer 10. As for the microscope apparatus 200′, it is preferable to provide such a telecentric optical system that the angles of incidence of the illumination light are identical at respective points on the wafer, and the diffracted lights having the same outgoing angle are received by the image sensor from respective points on the wafer. The requirements of the respective embodiments described above can be appropriately combined. Such a case is also assumed that a part or parts of the constitutive element or elements is/are not used. The disclosures of all of the patent publications and the U.S. patents in relation to, for example, the inspection apparatus as cited in the respective embodiments and the modified embodiments described above are incorporated herein by reference within a range of permission of the laws and ordinances.

### REFERENCE SIGNS LIST

1: surface inspection apparatus
10: wafer (10a, 10b: condition-varied wafer)
20: illumination system (illuminator)
30: light-receiving system (detector)
35: image pickup device (detector)
40: image processing unit
42: inspection unit (measuring unit)
45: storage unit
50: main controller
100: exposure system
101: exposure apparatus
200, 200′: microscope apparatus.

What is claimed is:

1-21. (canceled)

22. A measuring apparatus comprising:
an illuminator configured to illuminate, with an illumination light, a substrate having a pattern formed by exposure on a surface;
a detector configured to detect the illumination light modulated by the pattern to output a detection signal; and
a measuring unit configured to measure an exposure condition of the pattern of a desired portion by using the detection signals detected at a plurality of portions of the pattern.

23. The measuring apparatus according to claim 22, wherein the measuring unit is configured to measure the exposure condition of the pattern of the desired portion by using the detection signals detected at a plurality of portions including the desired portion.

24. The measuring apparatus according to claim 22, wherein the measuring unit is configured to measure the exposure condition of the pattern of the desired portion from the detection signal detected at a portion disposed around the desired portion.

25. The measuring apparatus according to claim 22, wherein the measuring unit is configured to measure the exposure condition of the pattern of the desired portion from the detection signal detected at the desired portion and a signal corresponding to the desired portion determined from the detection signal detected at a portion other than the desired portion.

26. The measuring apparatus according to claim 24, wherein the measuring unit is configured to determine the detection signal corresponding to the desired portion by interpolation from the signal detected at the portion disposed around the desired portion.

27. The measuring apparatus according to claim 25, wherein the measuring unit is configured to measure the exposure condition of the pattern of the desired portion by using the detection signals detected at the desired portion and the portion disposed around the desired portion, the portion disposed around the desired portion being correlated with the desired portion.

28. The measuring apparatus according to claim 22, wherein a detection condition for detecting the modulated illumination light is set for each of the portions.

29. The measuring apparatus according to claim 22, wherein the detector detects modulation based on diffraction or polarization caused by the pattern.

30. The measuring apparatus according to claim 22, further comprising:
a storage unit configured to previously store the detection signals detected with patterns formed in a plurality of exposure conditions,
wherein the measuring unit is configured to measure the exposure condition of the pattern of the desired portion on the surface by comparing the detection signal stored in the storage unit with the detection signal detected by the detector.

31. The measuring apparatus according to claim 22, wherein the exposure condition measured by the measuring unit is at least one of a focus state and an exposure amount in the exposure.

32. A measuring method comprising:
illuminating, with an illumination light, a substrate having a pattern formed by exposure on a surface;
detecting the illumination light modulated by the pattern to output a detection signal; and
measuring an exposure condition of the pattern of a desired portion by using the detection signals detected at a plurality of portions of the pattern.

33. The measuring method according to claim 32, wherein the exposure condition of the pattern of the desired portion is measured by using the detection signals detected at a plurality of portions including the desired portion.

34. The measuring method according to claim 32, wherein the exposure condition of the patter of the desired portion is measured from the detection signal detected at the desired portion and a signal corresponding to the desired portion determined from the detection signal detected at a portion other than the desired portion.

35. The measuring method according to claim 32, wherein a signal corresponding to the desired portion is determined from the detection signal detected in a partial area around the desired portion to measure the exposure condition of the pattern of the desired portion.

36. The measuring method according to claim 34, wherein the detection signal corresponding to the desired portion is determined by means of interpolation from the signal detected at the portion disposed around the desired portion.

37. The measuring method according to claim 34, wherein the exposure condition of the pattern of the desired portion is measured from the detection signal detected at the desired portion and a signal corresponding to the desired portion determined from the detection signal detected at a correlated portion correlated with the desired portion, the correlated portion being other than the desired portion.

38. The measuring method according to claim 32, wherein a detection condition for detecting the modulated illumination light is set for each of the portions.

39. The measuring method according to claim 32, wherein modulation based on diffraction or polarization caused by the pattern is detected in the detection.

40. The measuring method according to claim 32, further comprising:
previously storing the detection signals detected with patterns formed in a plurality of exposure conditions; and
measuring the exposure condition of the pattern of the desired portion on the surface by comparing the stored detection signal with the detected detection signal.

41. The measuring method according to claim 32, wherein the exposure condition to be measured is at least one of a focus state and an exposure amount in the exposure.

42. A method for producing a semiconductor device, including a lithography of exposing a surface of a substrate with a pattern, the method for producing the semiconductor device comprising:
measuring an exposure condition during the exposure for the substrate provided with the pattern by using the measuring method as defined in claim 32 after the exposure;
correcting an exposure condition based on the measured exposure condition; and
exposing the surface of the substrate with the pattern under a corrected exposure condition.
